(19) United States
(12) Patent Application Publication
(10) Pub. No.: US 2026/0239764 A1
(43) Pub. Date: Aug. 13, 2026

(54) METHOD FOR MANUFACTURING LIGHT DETECTION DEVICE AND LIGHT DETECTION DEVICE

(71) Applicant: SONY SEMICONDUCTOR SOLUTIONS CORPORATION, KANAGAWA (JP)

(72) Inventors: RIKIICHI OONO, KANAGAWA (JP); JUN YOSHIGIWA, KANAGAWA (JP)

(21) Appl. No.: 19/157,467

(22) PCT Filed: Feb. 22, 2024
(86) PCT No.: PCT/JP2024/006651

§ 371 Date: Aug. 18, 2025

(30) Foreign Application Priority Data
Mar. 9, 2023 (JP) 2023-036631

(51) Int. Cl. H10F 39/00; H10F 39/18

(52) U.S. Cl. CPC H10F 39/807; H10F 39/014; H10F 39/182

(57) ABSTRACT

Provided is a method for manufacturing a light detection device and the light detection device, achieving a finer pattern of pixels. A method for manufacturing a light detection device, the method including the steps of: forming a first trench by etching a portion of a semiconductor substrate between pixels from a first surface of the semiconductor substrate that has the first surface and a second surface located on the opposite side from the first surface and has the plurality of pixels arranged in a matrix; embedding a first material film into the first trench; and forming a second trench by etching another portion between the pixels of the semiconductor substrate from the first surface of the semiconductor substrate having the embedded first material film.

### TECHNICAL FIELD

The present disclosure relates to a method for manufacturing a light detection device and the light detection device.

### BACKGROUND ART

A known structure in an image sensor includes a trench between adjacent pixels (for example, see PTL 1).

### CITATION LIST

### Patent Literature

[PTL 1]

U.S. Patent Application Publication No. 2017/0012066 (Specification)

### SUMMARY

### Technical Problem

Image sensors have been miniaturized with the size reduction of products. Techniques that allow a finer pattern of pixels have been demanded.

An object of the present disclosure is to provide a method for manufacturing a light detection device and the light detection device that allow a finer pattern of pixels.

### Solution to Problem

A method for manufacturing a light detection device according to an aspect of the present disclosure, the method including the steps of: forming a first trench by etching a portion of a semiconductor substrate between pixels from a first surface of the semiconductor substrate that has the first surface and a second surface located on the opposite side from the first surface and has the plurality of pixels arranged in a matrix; embedding a first material film into the first trench; and forming a second trench by etching another portion between the pixels of the semiconductor substrate from the first surface of the semiconductor substrate having the embedded first material film.

According to the method, in the step of forming the second trench, the first material film embedded in the first trench supports a pattern including the pixels adjacent to the second trench. Thus, the collapse of the pattern including the pixels adjacent to the second trench can be suppressed in a processing step such as wet cleaning after the second trench is formed.

As described above, the collapse of the pattern including the pixels can be suppressed, achieving a finer pattern of the pixels.

A light detection device according to an aspect of the present disclosure includes: a semiconductor substrate having a first surface and a second surface located on the opposite side from the first surface; a plurality of pixels arranged in a matrix on the semiconductor substrate; and an inter-pixel separation portion that is provided between the pixels of the semiconductor substrate and separates one of the adjacent pixels and the other pixel. The inter-pixel separation portion includes: a first trench parallel to a first direction in a plan view from the direction of the normal to the first surface; a second trench parallel to a second direction that crosses the first direction in the plan view; an intersection region where the first trench and the second trench cross each other; and a first material film embedded in the first trench. The first material film protrudes from the first trench to the intersection region.

With this configuration, the pixel region can be formed using the method for manufacturing the light detection device, achieving a finer pattern of the pixels.

A light detection device according to another aspect of the present disclosure includes: a semiconductor substrate having a first surface and a second surface located on the opposite side from the first surface; a plurality of pixels arranged in a matrix on the semiconductor substrate; and an inter-pixel separation portion that is provided between the pixels of the semiconductor substrate and separates one of the adjacent pixels and the other pixel. In a plan view from the direction of the normal to the first surface, each of the pixels has a first corner; and a second corner having a smaller radius of curvature than the first corner. With this configuration, the pixel region can be formed using the method for manufacturing the light detection device, achieving a finer pattern of the pixels.

### BRIEF DESCRIPTION OF DRAWINGS

FIG. 1 is a block diagram showing an overall configuration example of an imaging device according to a first embodiment of the present disclosure.

FIG. 2 is a plan view showing a configuration example of the pixel region of the imaging device according to the first embodiment of the present disclosure.

FIG. 3 is an enlarged plan view of a pixel shown in FIG. 2.

FIG. 4 is a cross-sectional view taken along line X-X′ of the plan view in FIG. 2.

FIG. 5 is a cross-sectional view taken along line Y-Y′ of the plan view in FIG. 2.

FIG. 6A illustrates a method for manufacturing the pixel region in the order of steps according to the first embodiment of the present disclosure.

FIG. 6B illustrates the method for manufacturing the pixel region in the order of steps according to the first embodiment of the present disclosure.

FIG. 6C illustrates the method for manufacturing the pixel region in the order of steps according to the first embodiment of the present disclosure.

FIG. 6D illustrates the method for manufacturing the pixel region in the order of steps according to the first embodiment of the present disclosure.

FIG. 6E illustrates the method for manufacturing the pixel region in the order of steps according to the first embodiment of the present disclosure.

FIG. 6F illustrates the method for manufacturing the pixel region in the order of steps according to the first embodiment of the present disclosure.

FIG. 6G illustrates the method for manufacturing the pixel region in the order of steps according to the first embodiment of the present disclosure.

FIG. 6H illustrates the method for manufacturing the pixel region in the order of steps according to the first embodiment of the present disclosure.

FIG. 6I illustrates the method for manufacturing the pixel region in the order of steps according to the first embodiment of the present disclosure.

FIG. 6J illustrates the method for manufacturing the pixel region in the order of steps according to the first embodiment of the present disclosure.

FIG. 6K illustrates the method for manufacturing the pixel region in the order of steps according to the first embodiment of the present disclosure.

FIG. 6L illustrates the method for manufacturing the pixel region in the order of steps according to the first embodiment of the present disclosure.

FIG. 6M illustrates the method for manufacturing the pixel region in the order of steps according to the first embodiment of the present disclosure.

FIG. 6N illustrates the method for manufacturing the pixel region in the order of steps according to the first embodiment of the present disclosure.

FIG. 6O illustrates the method for manufacturing the pixel region in the order of steps according to the first embodiment of the present disclosure.

FIG. 6P illustrates the method for manufacturing the pixel region in the order of steps according to the first embodiment of the present disclosure.

FIG. 7A illustrates a method for manufacturing a pixel region in the order of steps according to a second embodiment of the present disclosure.

FIG. 7B illustrates the method for manufacturing the pixel region in the order of steps according to the second embodiment of the present disclosure.

FIG. 7C illustrates the method for manufacturing the pixel region in the order of steps according to the second embodiment of the present disclosure.

FIG. 7D illustrates the method for manufacturing the pixel region in the order of steps according to the second embodiment of the present disclosure.

FIG. 8 illustrates first and second trenches and the shapes of pixels in the pixel region according to the second embodiment of the present disclosure.

FIG. 9 is a plan view showing the configuration of a pixel region according to a first modification example of the second embodiment of the present disclosure.

FIG. 10A illustrates a method for manufacturing a pixel region in the order of steps

FIG. 10B illustrates the method for manufacturing the pixel region in the order of steps according to the third embodiment of the present disclosure.

FIG. 10C illustrates the method for manufacturing the pixel region in the order of steps according to the third embodiment of the present disclosure.

FIG. 10D illustrates the method for manufacturing the pixel region in the order of steps according to the third embodiment of the present disclosure.

FIG. 10E illustrates the method for manufacturing the pixel region in the order of steps according to the third embodiment of the present disclosure.

FIG. 10F illustrates the method for manufacturing the pixel region in the order of steps according to the third embodiment of the present disclosure.

FIG. 11A illustrates a method for manufacturing a pixel region in the order of steps according to a fourth embodiment of the present disclosure.

FIG. 11B illustrates the method for manufacturing the pixel region in the order of steps according to the fourth embodiment of the present disclosure.

FIG. 11C illustrates the method for manufacturing the pixel region in the order of steps according to the fourth embodiment of the present disclosure.

FIG. 11D illustrates the method for manufacturing the pixel region in the order of steps according to the fourth embodiment of the present disclosure.

FIG. 11E illustrates the method for manufacturing the pixel region in the order of steps according to the fourth embodiment of the present disclosure.

FIG. 12A illustrates a method for manufacturing a pixel region in the order of steps according to a fifth embodiment of the present disclosure.

FIG. 12B illustrates the method for manufacturing the pixel region in the order of steps according to the fifth embodiment of the present disclosure.

FIG. 12C illustrates the method for manufacturing the pixel region in the order of steps according to the fifth embodiment of the present disclosure.

FIG. 12D illustrates the method for manufacturing the pixel region in the order of steps according to the fifth embodiment of the present disclosure.

FIG. 12E illustrates the method for manufacturing the pixel region in the order of steps according to the fifth embodiment of the present disclosure.

### DESCRIPTION OF EMBODIMENTS

Embodiments of the present disclosure will be described below with reference to the drawings. In the illustrations of the drawings referred to in the following description, the same or similar portions are denoted by the same or similar reference numerals. However, it should be noted that the drawings are schematic and the relationships between the thicknesses and planar dimensions and the ratios of thicknesses of layers are different from actual ones. Therefore, specific thicknesses and dimensions should be determined in light of the following descriptions. In addition, it goes without saying that the drawings include portions having different dimensional relationships and ratios.

In addition, it is to be understood that definitions of directions such as upward and downward in the following description are merely definitions provided for the sake of brevity and are not intended to limit the technical idea of the present disclosure. For example, it is obvious that when an object is observed after being rotated by 90 degrees, up-down is converted into and interpreted as left-right, and when an object is observed after being rotated by 180 degrees, up-down is interpreted as being inverted.

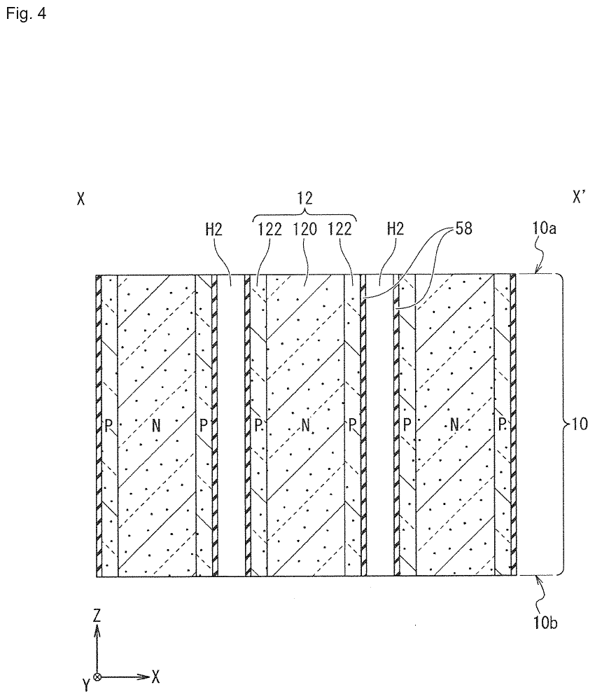

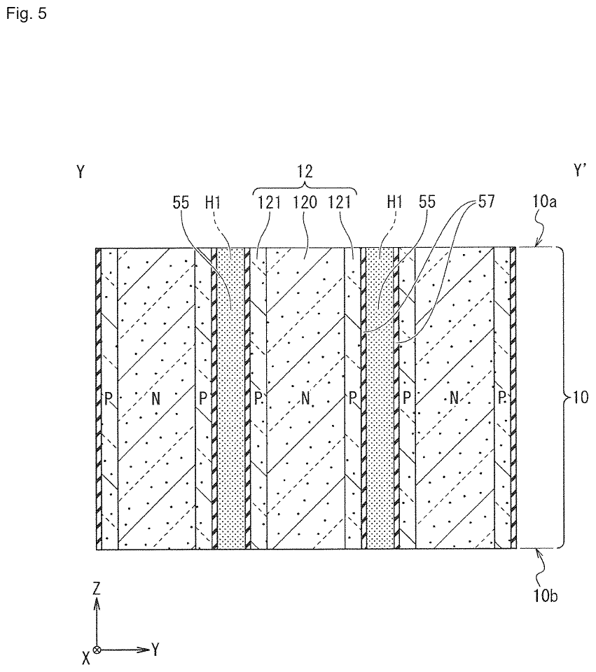

In the following description, the directions may be explained using terms such as the X-axis direction, the Y-axis direction, and the Z-axis direction. For example, the Z-axis direction is the direction of normal to a front side 10a of a semiconductor substrate 10 (see FIGS. 4 and 5, which will be described later) and the thickness direction of the semiconductor substrate 10. The X-axis direction and the Y-axis direction are directions orthogonal to the Z-axis direction. The X-axis direction, the Y-axis direction, and the Z-axis direction are orthogonal to each other.

In the following description, “plan view” refers to a view in the direction of normal to the front side 10a of the semiconductor substrate 10 (or the direction of normal to the back side 10b (see FIGS. 4 and 5 described later) parallel to the front side 10a), for example, a view in the Z-axis direction.

### First Embodiment

### Example of Overall Configuration of Imaging Device

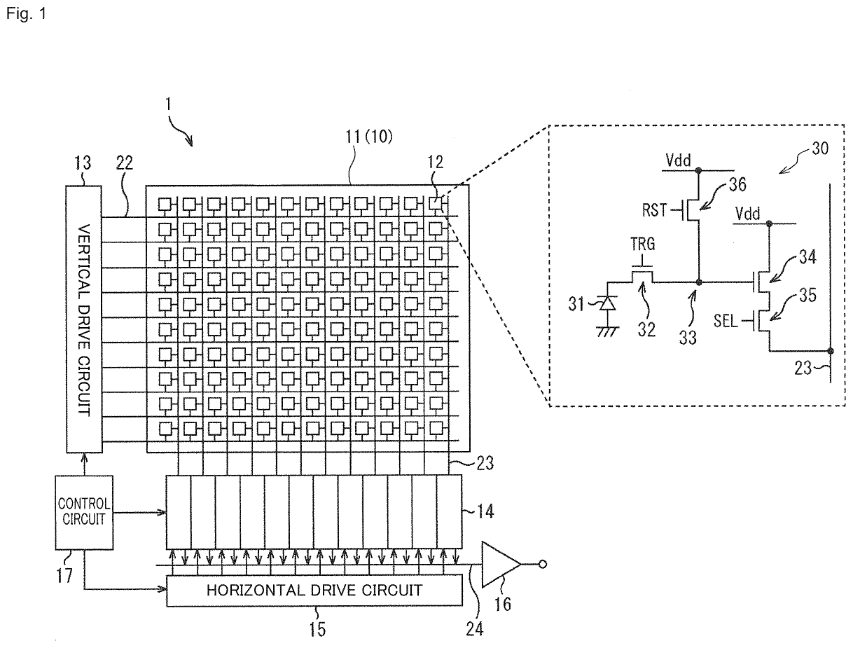

FIG. 1 is a block diagram showing an overall configuration example of an imaging device 1 according to a first embodiment of the present disclosure. The imaging device 1 is an example of “light detection device” of the present disclosure. The imaging device 1 is, for example, a back illuminated complementary metal oxide semiconductor (CMOS) image sensor used for electronic devices such as digital still cameras and video cameras. The imaging device 1 captures incident light (image light) from a subject through an optical lens system (not shown), converts the amount of the incident light forming an image on an imaging surface into an electrical signal for each pixel, and outputs the electrical signal as a pixel signal.

As shown in FIG. 1, the imaging device 1 (an example of “light detection device” of the present disclosure) includes a plurality of pixels 12, a vertical drive circuit 13, a column signal processing circuit 14, a horizontal drive circuit 15, an output circuit 16, and a control circuit 17.

The pixel 12 is a light-receiving region that receives light collected by an optical system (not shown). The plurality of pixels 12 are arranged in a matrix in a pixel region 11 of the semiconductor substrate 10. The plurality of pixels 12 are connected to the vertical drive circuit 13 on a row-by-row basis via horizontal signal lines 22 and are connected to the column signal processing circuit 14 on a column-by-column basis via vertical signal lines 23. Each of the pixels 12 outputs a pixel signal at a level corresponding to the amount of received light. A subject image is constructed from the pixel signals.

The vertical drive circuit 13 supplies drive signals for driving (transferring, selecting, resetting, or the like) the pixels 12, to the pixels 12 sequentially for each row of the pixels 12 via the horizontal signal lines 22. The column signal processing circuit 14 performs AD conversion on the pixel signals output from the plurality of pixels 12 via the vertical signal lines 23 and removes reset noise by performing correlated double sampling (CDS) processing on the pixel signals.

The horizontal drive circuit 15 sequentially supplies, to the column signal processing circuit 14 for each column of the pixels 12, drive signals for outputting pixel signals from the column signal processing circuit 14 to a data output signal line 24. The output circuit 16 amplifies the pixel signal supplied from the column signal processing circuit 14 via the data output signal line 24 at a timing according to the drive signal of the horizontal drive circuit 15, and outputs the pixel signal to the subsequent signal processing circuit. The control circuit 17 controls the driving of each block in the imaging device 1. For example, the control circuit 17 generates a clock signal according to the drive cycle of each block and supplies the clock signal to each block.

The pixel 12 includes a photodiode 31, a transfer transistor 32, a floating diffusion 33, an amplification transistor 34, a selection transistor 35, and a reset transistor 36. The transfer transistor 32, the floating diffusion 33, the amplification transistor 34, the selection transistor 35, and the reset transistor 36 constitute a readout circuit 30 that reads out charge (pixel signal) photoelectrically converted in the photodiode 31.

The photodiode 31 is a photoelectric conversion unit that photoelectrically converts incident light into charge and accumulates the charge, and has the grounded anode terminal and the cathode terminal connected to the transfer transistor 32. The transfer transistor 32 is driven according to a transfer signal TRG supplied from the vertical drive circuit 13, and when the transfer transistor 32 is turned on, the charges accumulated in the photodiode 31 are transferred to the floating diffusion 33. The floating diffusion 33 is a floating diffusion region connected to the gate electrode of the amplification transistor 34 and having a predetermined storage capacity. The floating diffusion 33 temporarily stores the charge transferred from the photodiode 31.

The amplification transistor 34 outputs a pixel signal of the level corresponding to the charge accumulated in the floating diffusion 33 (that is, the potential of the floating diffusion 33) to the vertical signal line 23 via the selection transistor 35.

In other words, in the configuration in which the floating diffusion 33 is connected to the gate electrode of the amplification transistor 34, the floating diffusion 33 and the amplification transistor 34 function as conversion units that amplify the charge generated in the photodiode 31 and convert the charge into a pixel signal of the level corresponding to the charge.

The selection transistor 35 is driven according to a selection signal SEL supplied from the vertical drive circuit 13. When the selection transistor 35 is turned on, the pixel signal output from the amplification transistor 34 can be output to the vertical signal line 23. The reset transistor 36 is driven according to a reset signal RST supplied from the vertical drive circuit 13. When the reset transistor 36 is turned on, the charge accumulated in the floating diffusion 33 is discharged to a drain power supply Vdd to reset the floating diffusion 33.

### (Configuration Example of Pixel Region)

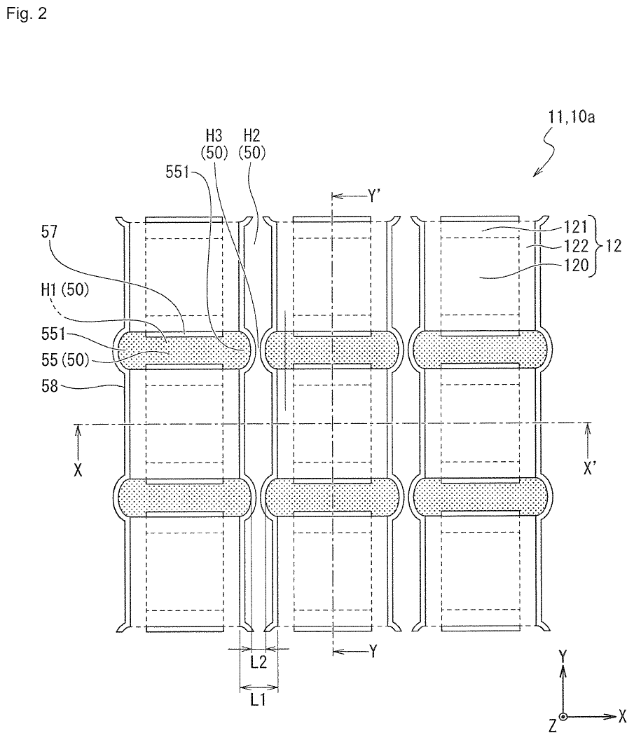

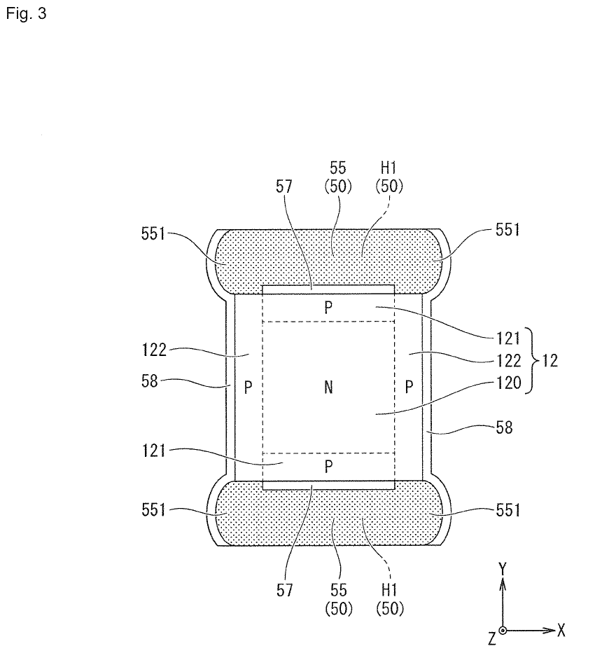

FIG. 2 is a plan view showing a configuration example of the pixel region 11 of the imaging device 1 according to the first embodiment of the present disclosure. FIG. 3 is an enlarged plan view of the pixel 12 shown in FIG. 2. FIG. 4 is a cross-sectional view taken along line X-X′ of the plan view in FIG. 2. FIG. 5 is a cross-sectional view taken along line Y-Y′ of the plan view in FIG. 2.

As shown in FIGS. 2 to 5, the imaging device 1 includes the semiconductor substrate 10 having the front side 10a (an example of “first surface” of the present disclosure) and a back side 10b located on the opposite side from the front side 10a, the plurality of pixels 12 arranged in a matrix in the pixel region 11 of the semiconductor substrate 10, and inter-pixel separation portions 50, each being provided in the pixel region 11 of the semiconductor substrate 10 and separating one of the adjacent pixels 12 and the other pixel 12 (that is, separating the pixels). Since the imaging device 1 is, for example, a back-illuminated type, the back side 10b of the semiconductor substrate 10 serves as the light receiving surface.

The semiconductor substrate 10 is, for example, a single-crystal silicon layer formed by polishing a silicon wafer by chemical mechanical polishing (CMP). The semiconductor substrate 10 includes the photodiode 31 (see FIG. 1) for each of the pixels 12. The thickness of the semiconductor substrate 10 may be set arbitrarily according to the wavelength of received light.

As shown in FIG. 2, the plurality of pixels 12 are disposed at regular intervals in, for example, the X-axis direction and the Y-axis direction. As shown in FIGS. 2 and 3, each of the pixels 12 includes an N-type region having N-type conductivity and a P-type region having P-type conductivity. The N-type region and the P-type region are joined to form a PN junction. The photodiode includes the PN junction.

The p-type region may also serve as a pinning layer. An electric field induced by the pinning layer can form a hole storage layer on the semiconductor substrate 10 in contact with the pinning layer, and suppress the generation of dark current due to the interface level of the semiconductor substrate 10 in contact with the pinning layer.

The several pixels 12 each have a single-crystal semiconductor layer formed on the outer periphery by an epitaxial growth method. For example, the pixel 12 has a central portion 120 located at the center of the pixel 12 in plan view, and first semiconductor layers 121 and second semiconductor layers 122 that are formed around the central portion 120 by the epitaxial growth method. The first semiconductor layer 121 is provided along the X-axis direction. The second semiconductor layer 122 is provided along the Y-axis direction.

The central portion 120 of the pixel 12 is single crystal silicon that is present as a part of a silicon wafer from the beginning of the manufacturing process. Out of the sides of the central portion 120, the first semiconductor layer 121 is formed on the sides along the X-axis direction by the epitaxial growth method, and the second semiconductor layer 122 is formed on the sides along the Y-axis direction by the epitaxial growth method. The first semiconductor layer 121 and the second semiconductor layer 122 are, for example, single-crystal silicon. Thus, an interatomic bond is continuous between the central portion 120 and the first and second semiconductor layers 121 and 122 of the pixel 12, and the central portion 120 and the first and second semiconductor layers 121 and 122 are integrated into single crystal silicon.

In the example shown in FIGS. 2 and 3, the central portion 120 of the pixel 12 is an N-type region, and the first semiconductor layer 121 and the second semiconductor layer 122, which are the outer peripheral portions of the pixel 12, are P-type regions, respectively. This configuration is merely an example. The boundary between the central portion 120 and the outer periphery of the pixel 12 and the interface of the PN junction may or may not be aligned with each other.

The inter-pixel separation portion 50 is provided between the pixels 12 arranged at regular intervals in the X-axis direction and the Y-axis direction. For example, the inter-pixel separation portion 50 includes a first trench H1 parallel to the X-axis direction (an example of “first direction” of the present disclosure), a second trench H2 parallel to the Y-axis direction that crosses the X-axis direction in the plan view (an example of “second direction” of the present disclosure), an intersection region H3 where the first trench H1 and the second trench H2 cross each other, and a polysilicon film 55 (an example of “first material film” and “polycrystalline film” of the present disclosure) embedded in the first trench H1.

The first trench H1 and the polysilicon film 55 are provided between one of the pixels 12 adjacent to each other in the Y-axis direction and the other pixel 12. Also, as shown in FIG. 3, a side of the first trench H1 (that is, a side of the first semiconductor layer 121) is covered with an insulating film 57. The insulating film 57 is interposed between the first semiconductor layer 121 and the polysilicon film 55. The first trench H1, the polysilicon film 55, and the insulating film 57 separate one of the pixels 12 adjacent to each other in the Y-axis direction and the other pixel 12.

The second trench H2 is provided between one of the pixels 12 adjacent to each other in the X-axis direction and the other pixel 12. As shown in FIG. 3, a side of the second trench H2 (that is, a side of the second semiconductor layer 122) is covered with an insulating film 58. The inter-pixel separation portion 50 has a gap in the second trench H2. A material film for inter-pixel separation is not embedded in the second trench H2. The second trench H2 and the insulating film 58 separate one of the pixels 12 adjacent to each other in the X-axis direction and the other pixel 12.

In addition, the polysilicon film 55 embedded in the first trench H1 protrudes from the first trench H1 to the intersection region H3. Hereinafter, a portion protruding from the polysilicon film 55 to the intersection region H3 will also be referred to as a protruding portion 551. A distance L2 between the protruding portion 551 of one of the polysilicon films 55 adjacent to each other in the X-axis direction and the protruding portion 551 of the other polysilicon film 55 is shorter than a distance L1 between one of the pixels 12 adjacent to each other in the X-axis direction and the other pixel 12.

The sides of the protruding portion 551 of the polysilicon film 55 are covered with the insulating film 58. The insulating film 58 continuously covers one side of the second semiconductor layer 122, which is a part of the outer periphery of the pixel 12 and one side of the protruding portion 551 of the polysilicon film 55, which is a part of the inter-pixel separation portion 50.

### (Method for Manufacturing Pixel Region)

A method for manufacturing the pixel region 11 including the pixels 12 and the inter-pixel separation portions 50 of the imaging device 1 will be described below.

The imaging device is manufactured by using various devices such as a resist coating device, an exposure device, an etching device, an ion implantation device, a plasma doping device, and a film deposition device (including a CVD device, an epitaxial growth device, a sputtering device, and a thermal oxidation device). Hereinafter, these devices will be collectively referred to as a manufacturing device.

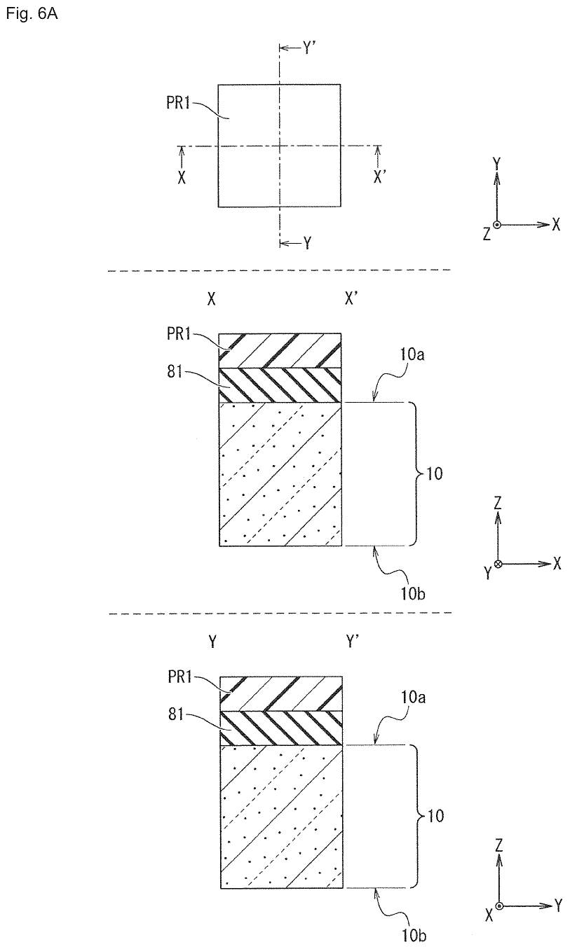

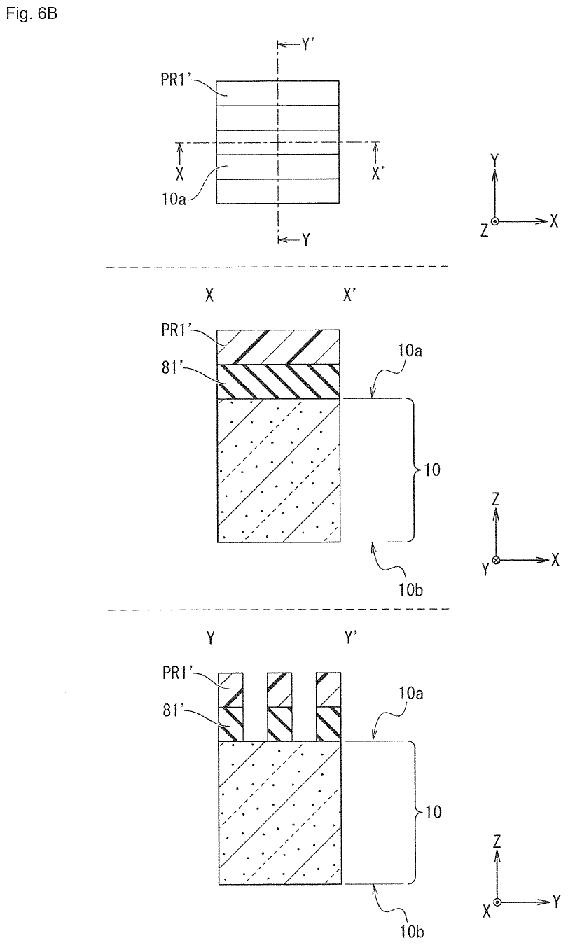

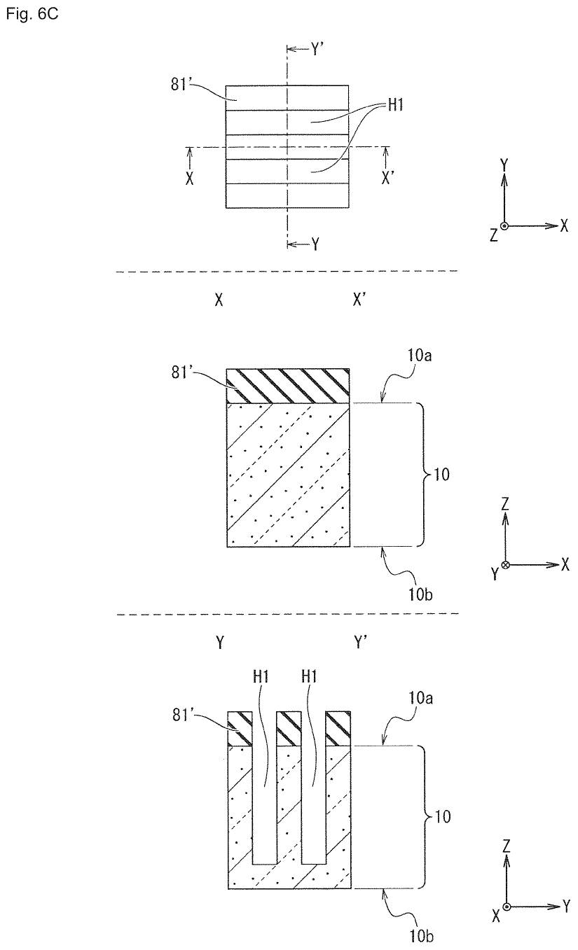

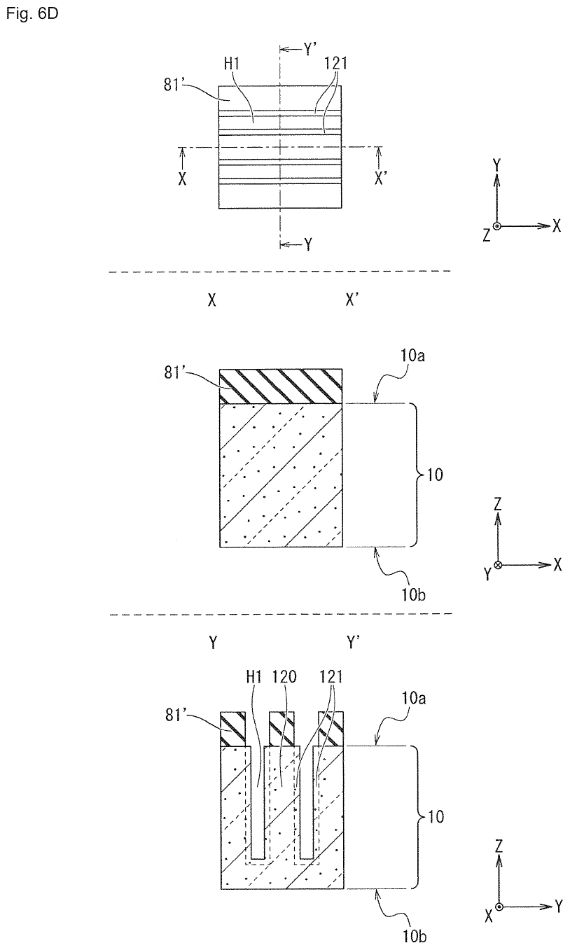

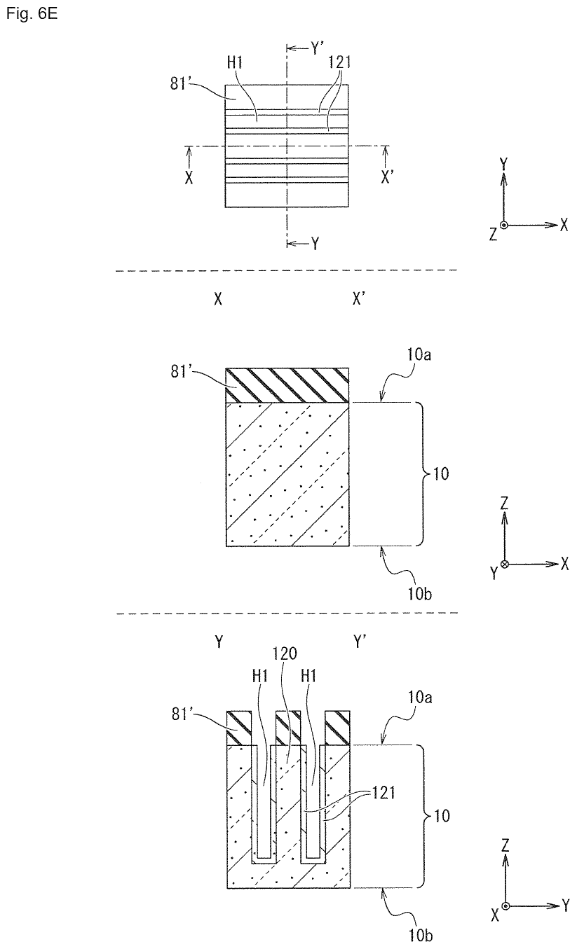

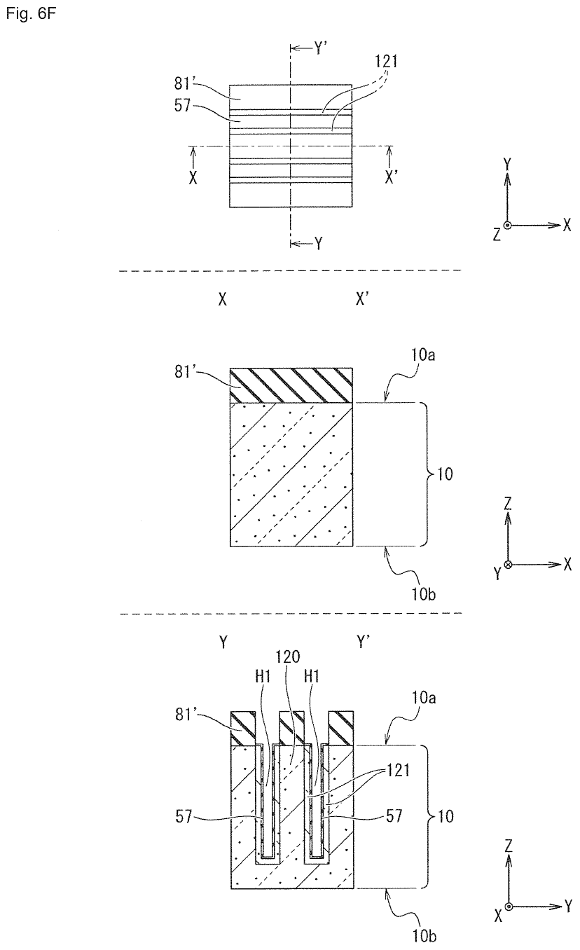

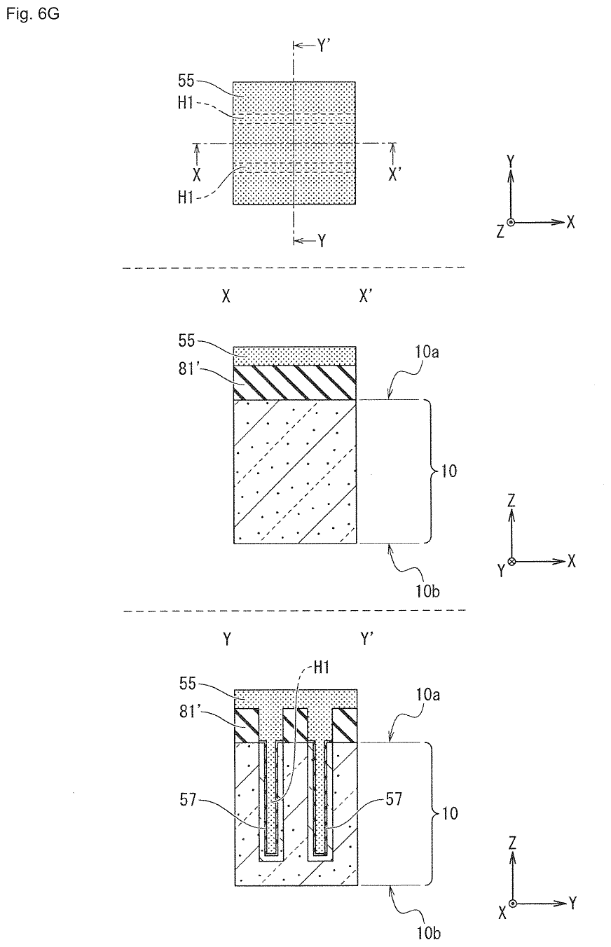

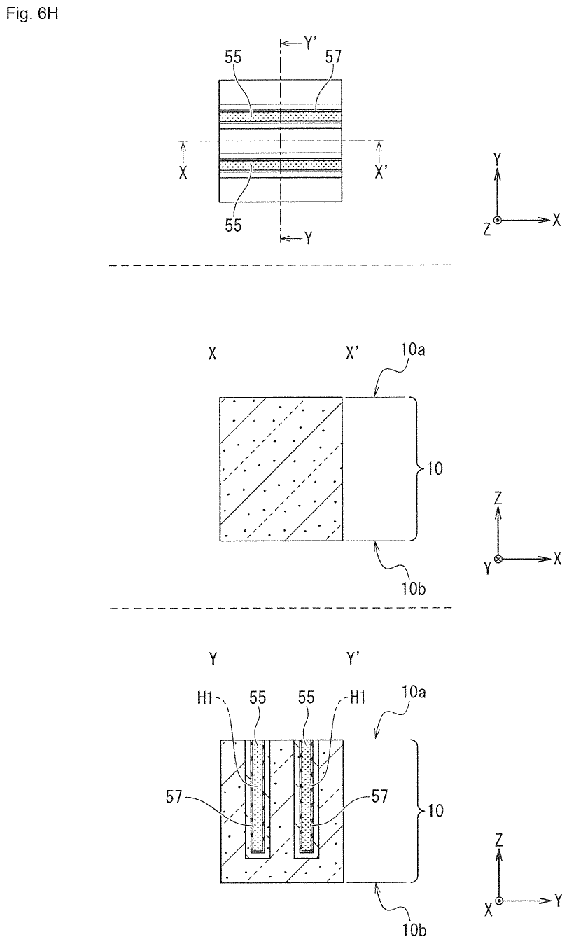

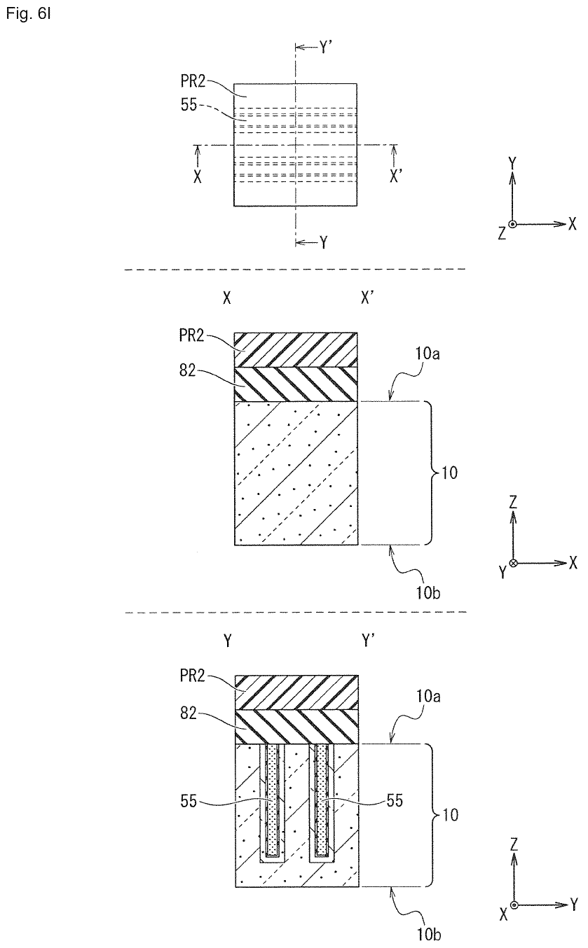

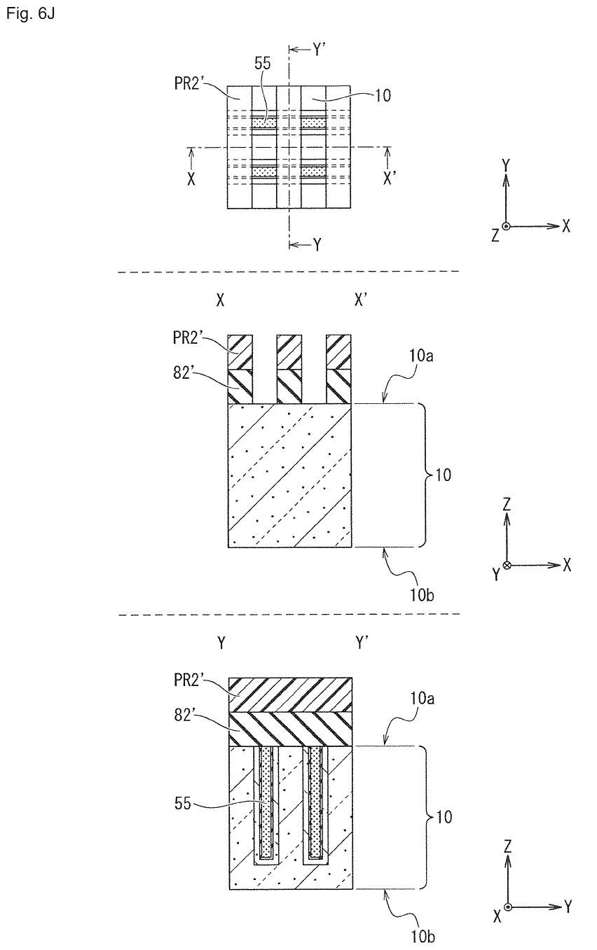

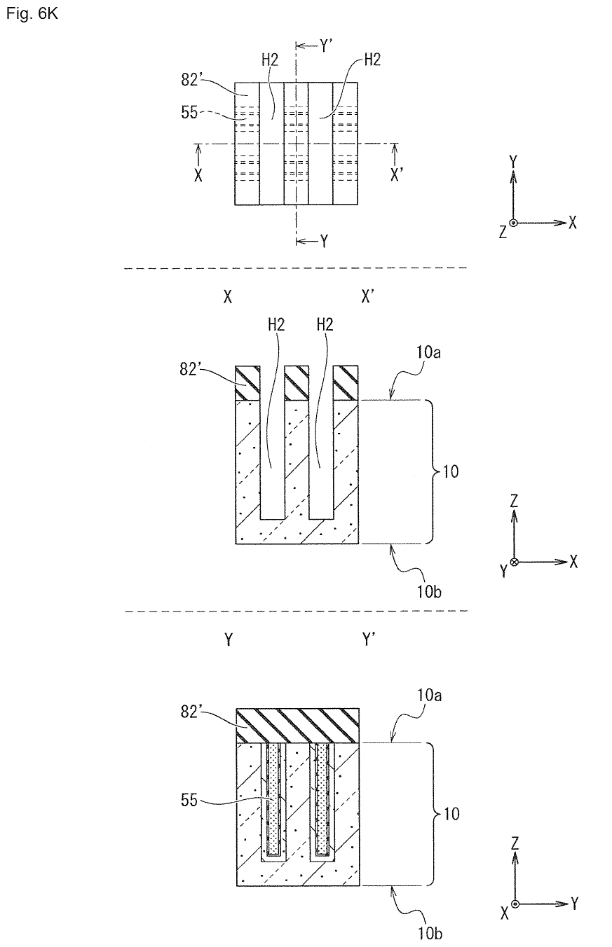

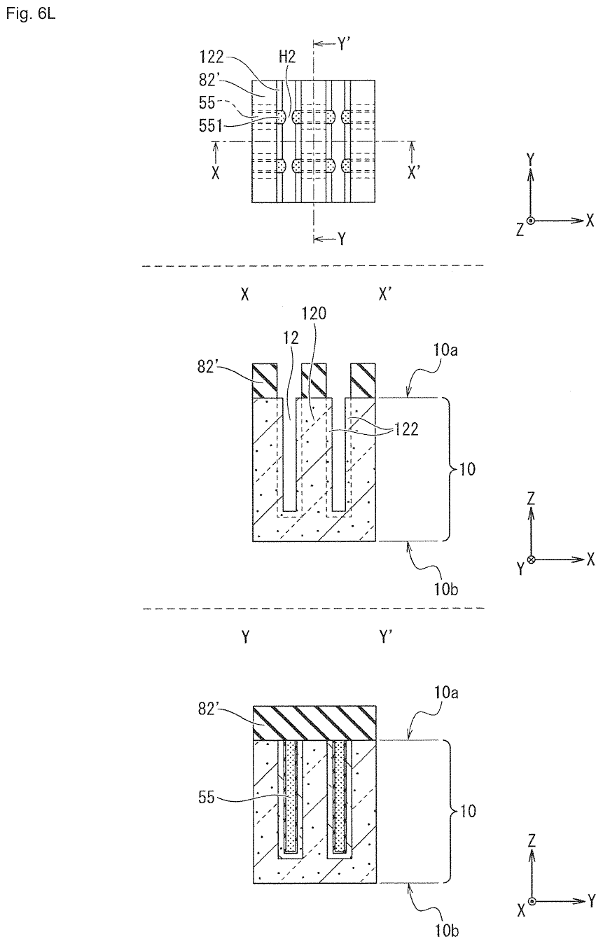

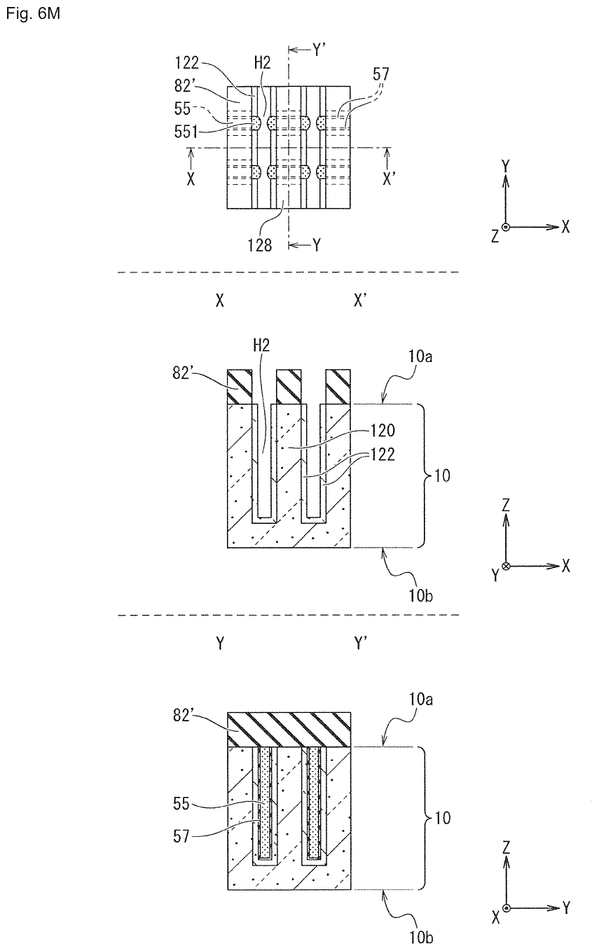

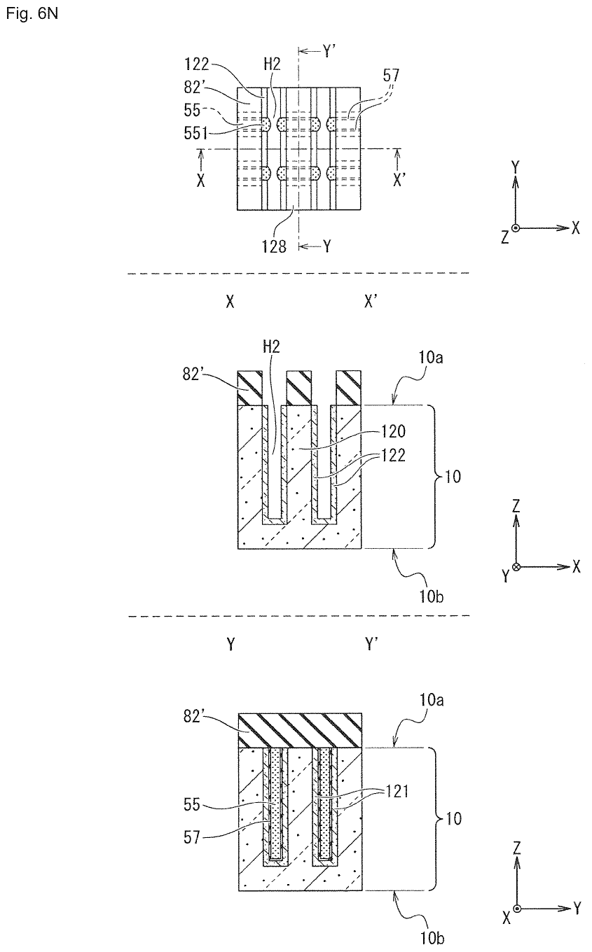

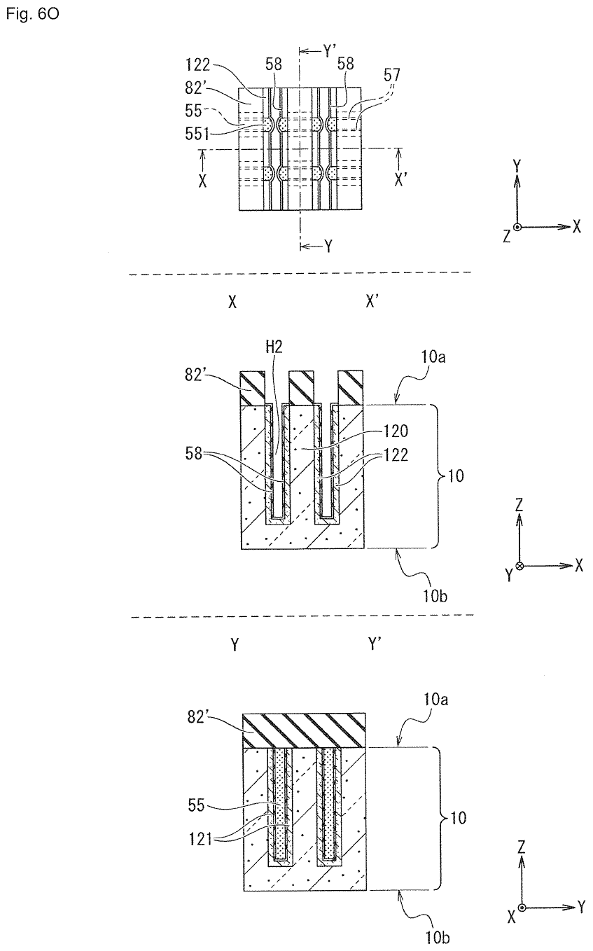

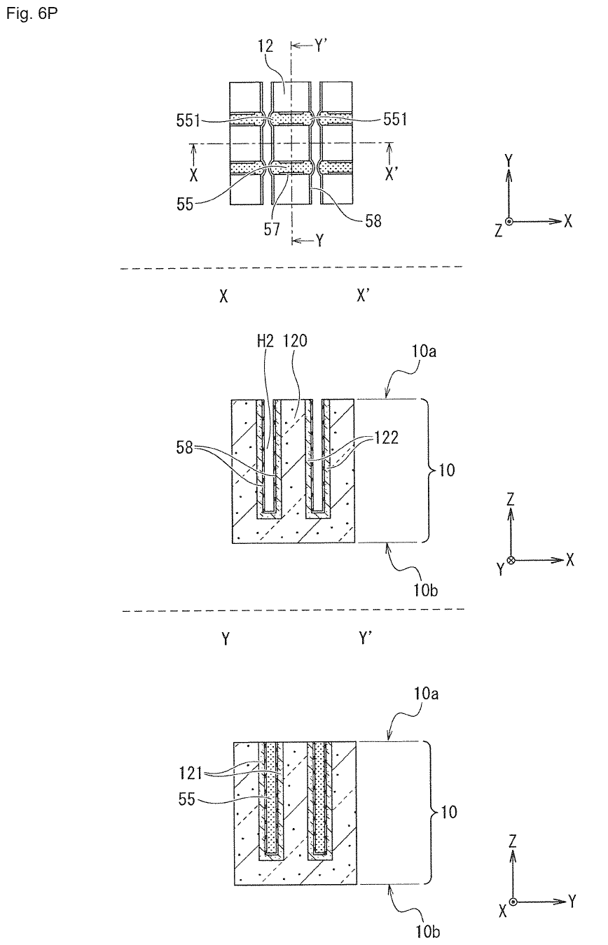

FIGS. 6A to 6P illustrate the method for manufacturing the pixel region 11 in the order of steps according to the first embodiment of the present disclosure. In the drawings of FIGS. 6A to 6P, the upper drawing is a plan view from the front side 10a of the semiconductor substrate 10, the middle drawing is a cross-sectional view taken along line X-X′ of the upper plan view, and the lower drawing is a cross-sectional view taken along line Y-Y′ of the upper plan view.

As shown in FIG. 6A, the manufacturing device forms an insulating film 81 on the front side 10a of the semiconductor substrate 10. The semiconductor substrate 10 is, for example, a silicon substrate, and the insulating film 81 is, for example, a silicon oxide film. The insulating film 81 is formed by, for example, CVD. The manufacturing device then forms a photoresist PR1 on the insulating film 81.

Thereafter, as shown in FIG. 6B, the manufacturing device exposes the photoresist PR1 into the shape of an L/S pattern parallel to the X-axis and performs development processing on the photoresist PR1 to form a resist pattern PRI'. The L/S stands for Line/Space. The manufacturing device then etches the insulating film 81 with the resist pattern PR1′ serving as a mask. Thus, an insulating film pattern (hard mask) 81′ is formed from the insulating film 81. After the insulating film pattern 81′ is formed, the manufacturing device removes the resist pattern PRI'.

Thereafter, as shown in FIG. 6C, the manufacturing device etches the semiconductor substrate 10 from the front side 10a with the insulating film pattern 81′ serving as a mask, so that the first trenches H1 are formed. As shown in FIG. 6D, the manufacturing device then epitaxially grows the first semiconductor layer 121 on the sides and bottom of the first trench H1. Since the semiconductor substrate 10 serving as the base of the epitaxial growth is a single crystal, the first semiconductor layer 121 is also formed as a single crystal. The first semiconductor layer 121 is made of, for example, single crystal silicon.

The manufacturing device then performs plasma doping on the semiconductor substrate 10 with the insulating film pattern 81′ serving as a mask. Thus, as shown in FIG. 6E a P-type impurity such as boron (B) is introduced into the first semiconductor layer 121.

Subsequently, as shown in FIG. 6F, the manufacturing device forms the insulating film 57 on the sides and bottom of the first trench H1. The insulating film 57 is formed by, for example, thermal oxidation. As described above, the first semiconductor layer 121 is epitaxially grown on the sides and bottom of the first trench H1 and is plasma-doped. Hence, the insulating film 57 is formed by thermally oxidizing the plasma-doped first semiconductor layer 121. Alternatively, the insulating film 57 may be formed by CVD.

Subsequently, as shown in FIG. 6G, the manufacturing device deposits the polysilicon film 55 on the front side 10a of the semiconductor substrate 10 and fills the first trenches H1 with the polysilicon film 55 according to, for example, CVD. The manufacturing device then performs CMP processing sequentially on the polysilicon film 55 and the insulating film pattern 81′. Thus, as shown in FIG. 6H, the manufacturing device leaves the polysilicon film 55 in the first trenches H1 and removes the polysilicon film 55 and the insulating film pattern 81′ from regions other than the first trenches H1.

Subsequently, as shown in FIG. 6I, the manufacturing device forms an insulating film 82 on the front side 10a of the semiconductor substrate 10. The insulating film 82 is, for example, a silicon oxide film. The insulating film 82 is formed by, for example, CVD. The manufacturing device then forms a photoresist PR2 on the insulating film 82.

Subsequently, as shown in FIG. 6J, the manufacturing device exposes the photoresist PR2 into the shape of an L/S pattern parallel to the Y-axis and performs development processing on the photoresist PR2 to form a resist pattern PR2′. The manufacturing device then etches the insulating film 82 with the resist pattern PR2′ serving as a mask. Thus, an insulating film pattern (hard mask) 82′ is formed from the insulating film 82. After the insulating film pattern 82′ is formed, the manufacturing device removes the resist pattern PR2′.

Thereafter, as shown in FIG. 6K, the manufacturing device etches the semiconductor substrate 10 and the polysilicon film 55 from the front side 10a with the insulating film pattern 82′ serving as a mask, so that the second trenches H2 are formed. The polysilicon film 55 is divided by the second trenches H2.

Subsequently, as shown in FIG. 6L, the manufacturing device epitaxially grows the second semiconductor layer 122 on the sides and bottom of the second trench H2.

Since the semiconductor substrate 10 serving as the base of the epitaxial growth is a single crystal, the second semiconductor layers 122 is also formed as a single crystal. The second semiconductor layer 122 is made of, for example, single crystal silicon.

In the step of forming the second semiconductor layer 122 according to the epitaxial growth method, a semiconductor layer is additionally formed not only on the bottom and sides of the second trench H2 but also on the sides of the polysilicon film 55 facing the second trench H2. The additionally formed semiconductor layer serves as the protruding portion 551 of the polysilicon film 55. The protruding portion 551 is made of, for example, polysilicon. The protruding portion 551 is formed as a polycrystalline portion unlike the single-crystal second semiconductor layer 122 formed on a side of the second trench H2. The deposition rate of a polycrystal is faster than that of a single crystal. Therefore, the protruding portion 551 is formed to protrude in the X-axis direction from the second semiconductor layer 122.

The manufacturing device then performs plasma doping on the semiconductor substrate 10 with the insulating film pattern 82′ serving as a mask. Thus, as shown in FIG. 6M, a P-type impurity, e.g., boron (B) is introduced into the second semiconductor layer 122.

Subsequently, the manufacturing device performs heat treatment on the semiconductor substrate 10. Hence, as shown in FIG. 6N, the P-type impurity introduced into the first semiconductor layer 121 and the second semiconductor layer 122 is diffused and activated.

Subsequently, as illustrated in FIG. 60, the manufacturing device forms the insulating film 58 on the sides and bottom of the second trench H2. The insulating film 58 is formed by, for example, thermal oxidation. As described above, the second semiconductor layer 122 is epitaxially grown on the sides and bottom of the second trench H2 and is plasma-doped. Therefore, the insulating film 58 is formed by thermally oxidizing the plasma-doped second semiconductor layer 122.

Alternatively, the insulating film 58 may be formed by CVD.

Thereafter, as shown in FIG. 6P, the manufacturing device removes the insulating film pattern 82′. The manufacturing device grinds the back side 10b of the semiconductor substrate 10 such that the semiconductor substrate 10 has a foil thickness and the polysilicon film 55 is exposed from the back side 10b. Through these steps, the pixel region 11 including the pixels 12 and the inter-pixel separation portions 50 in FIGS. 5 to 5 is completed.

(Effects of First Embodiment) As described above, the method for manufacturing the pixel region 11 according to the first embodiment of the present disclosure includes: the step of forming the first trench H1 by etching a portion between the pixels of the semiconductor substrate 10 from the front side 10a of the semiconductor substrate 10 that has the front side 10a and the back side 10b located on the opposite side from the front side 10a and has the plurality of pixels 12 arranged in a matrix; the step of embedding the polysilicon film 55 into the first trench H1; and the step of forming the second trench H2 by etching another portion between the pixels of the semiconductor substrate 10 from the front side 10a of the semiconductor substrate 10 having the embedded polysilicon film 55.

For example, in the step of forming the first trench H1, the first trench H1 is formed in parallel with the X-axis direction in plan view. In the step of forming the second trench H2, the second trench H2 is formed in parallel with the Y-axis direction in plan view.

With this configuration, the first trenches H1 can be arranged sparsely at certain intervals as compared with the case where trenches for separating pixels are formed at a time. This configuration can secure a wide plane area (that is, an area in a plan view from the Z-axis direction) for a pattern including the pixels 12 adjacent to the first trench H1. Thus, the collapse of the pattern including the pixels 12 adjacent to the first trench H1 can be suppressed in a processing step such as wet cleaning (hereinafter simply referred to as wet processing) after the first trenches H1 are formed.

In the step of forming the second trenches H2, the polysilicon film 55 embedded in the first trenches H1 supports a pattern including the pixels 12 adjacent to the second trench H2. Thus, the collapse of the pattern including the pixels 12 adjacent to the second trench H2 (for example, the pixels 12) can be suppressed in a processing step such as wet cleaning (wet processing) after the second trenches H2 are formed.

In this way, the collapse of the pattern including the pixels 12 can be suppressed in wet processing after the first trenches H1 are formed and wet processing after the second trenches H2 are formed. In the step of forming the second trenches H2 and the subsequent wet processing, the polysilicon film 55 embedded in the first trench H1 serves as a support for the pattern including the pixels 12. This allows a finer pattern of the pixels 12.

The method for manufacturing the pixel region 11 according to the first embodiment further includes the step of epitaxially growing, on the sides of the first trench H1, the first semiconductor layer 121 made of the same material as the semiconductor substrate 10 before the step of embedding the polysilicon film 55 into the first trench H1.

This can reduce the width of the first trench H1 after the first trench H1 is formed. For example, a reduction in the width of the first trench H1 may exceed the minimum limit value of the processing width by etching. Since the light receiving area of the pixel 12 can be increased by the reduction in the width of the first trench H1, a decrease in Qs can be further suppressed.

The method for manufacturing the pixel region 11 according to the first embodiment further includes the step of epitaxially growing, on the sides of the second trench H2, the second semiconductor layer 122 made of the same material as the semiconductor substrate 10.

This can reduce the width of the second trench H2 after the second trench H2 is formed. For example, a reduction in the width of the second trench H2 may exceed the minimum limit value of the processing width by etching. Since the light receiving area of the pixel 12 can be increased by the reduction in the width of the second trench H2, a decrease in Qs (saturation charge amount) can be further suppressed. This can achieve both of a finer pattern of the pixels 12 and suppression of the decrease in Qs.

Furthermore, in the method for manufacturing the pixel region 11 according to the first embodiment, the polysilicon film 55 is embedded into the first trench H1. This enables gettering of metal or the like at the grain boundaries of the polysilicon film 55. Accordingly, the crystallinity of the pixels 12 adjacent to the polysilicon film 55 can be improved.

The pixel region 11 according to the first embodiment of the present disclosure includes the semiconductor substrate 10 having the front side 10a and the back side 10b, the plurality of pixels 12 arranged in a matrix on the semiconductor substrate 10, and inter-pixel separation portions 50, each being provided between the pixels on the semiconductor substrate 10 and separating one of the adjacent pixels 12 and the other pixel 12. The inter-pixel separation portion 50 includes the first trench H1 parallel to the X-axis direction in plan view, the second trench H2 parallel to the Y-axis direction in plan view, an intersection region H3 where the first trench H1 and the second trench H2 cross each other, and the polysilicon film 55 embedded in the first trench H1. The polysilicon film 55 protrudes from the first trench H1 to the intersection region H3.

With this configuration, the pixel region 11 can be formed using the manufacturing method according to the first embodiment, achieving a finer pattern of the pixels 12.

### Modification Example of First Embodiment

### (1) First Modification Example

The first embodiment described that the polysilicon film 55 is used as “first material film” of the present disclosure. However, the first embodiment of the present disclosure is not limited thereto. The “first material film” of the present disclosure may be an amorphous film such as a silicon oxide film.

Also in this configuration, the collapse of the pattern including the pixels 12 can be suppressed in wet processing after the first trenches H1 are formed and wet processing after the second trenches H2 are formed. In the step of forming the second trenches H2 and the subsequent wet processing, an amorphous film such as a silicon oxide film embedded in the first trench H1 serves as a support for the pattern including the pixels 12. This allows a finer pattern of the pixels 12.

Furthermore, gettering of metal or the like is allowed at the grain boundaries of the polysilicon oxide film embedded in the first trench H1. Accordingly, the crystallinity of the pixels 12 adjacent to the silicon oxide film embedded in the first trench H1 can be improved.

### (2) Second Modification Example

The first embodiment described that the second trench H2 has a gap. However, the first embodiment of the present disclosure is not limited thereto. The second trench H2 may be filled with a second material film. Examples of the second material film include a polysilicon film and a silicon oxide film.

Also in this configuration, the collapse of the pattern including the pixels 12 can be suppressed in wet processing after the first trenches H1 are formed and wet processing after the second trenches H2 are formed. In the step of forming the second trenches H2 and the subsequent wet processing, the polysilicon film 55 embedded in the first trench H1 serves as a support for the pattern including the pixels 12. This allows a finer pattern of the pixels 12.

### (3) Third Modification Example

In the above embodiment, as described with reference to FIG. 6P, the back side 10b of the semiconductor substrate 10 is ground such that the semiconductor substrate 10 has a foil thickness and the polysilicon film 55 embedded in the first trench H1 is exposed on the back side 10b. This describes that the inter-pixel separation portion 50 is formed so as to penetrate between the front side 10a and the back side 10b of the semiconductor substrate 10.

However, the first embodiment of the present disclosure is not limited thereto. In the first embodiment of the present disclosure, the polysilicon film 55 embedded in the first trench H1 may not be exposed when the back side 10b of the semiconductor substrate 10 is ground to have a foil thickness. Alternatively, the step of grinding the back side 10b of the semiconductor substrate 10 may be omitted. The inter-pixel separation portion 50 may be formed in a non-penetrating manner so as not to penetrate the front side 10a and the back side 10b of the semiconductor substrate 10.

Also in this configuration, the collapse of the pattern including the pixels 12 can be suppressed in wet processing after the first trenches H1 are formed and wet processing after the second trenches H2 are formed. In the step of forming the second trenches H2 and the subsequent wet processing, the polysilicon film 55 embedded in the first trench H1 serves as a support for the pattern including the pixels 12. This allows a finer pattern of the pixels 12.

### Second Embodiment

The foregoing first embodiment described that the first trench H1 is formed in the shape of an L/S pattern parallel to the X-axis direction, the first trench H1 is filled with the polysilicon film 55, and then the second trench H2 is formed in the shape of an L/S pattern parallel to the Y-axis direction. However, in the embodiments of the present disclosure, the shapes of the first and second trenches H1 and H2 in plan view are not limited to the L/S pattern. Each of the first trench H1 and the second trench H2 may be each formed in, for example, a lattice pattern in plan view.

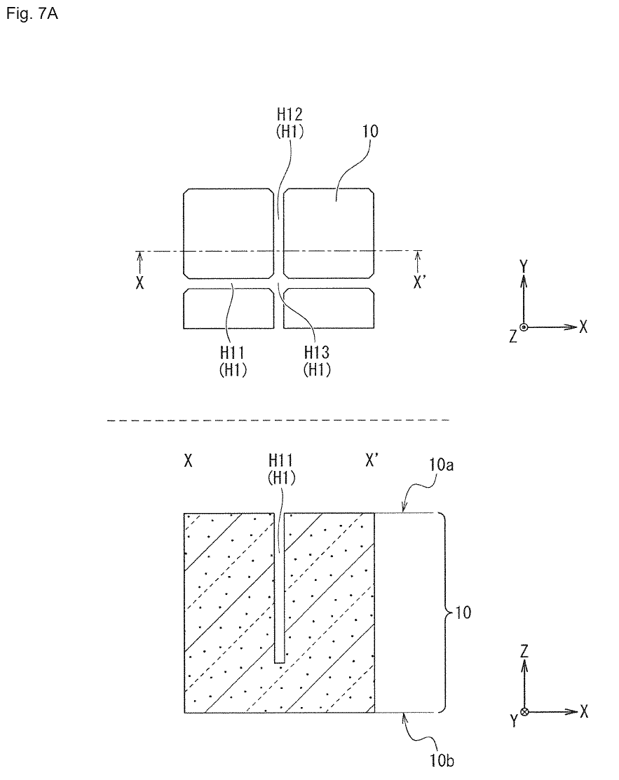

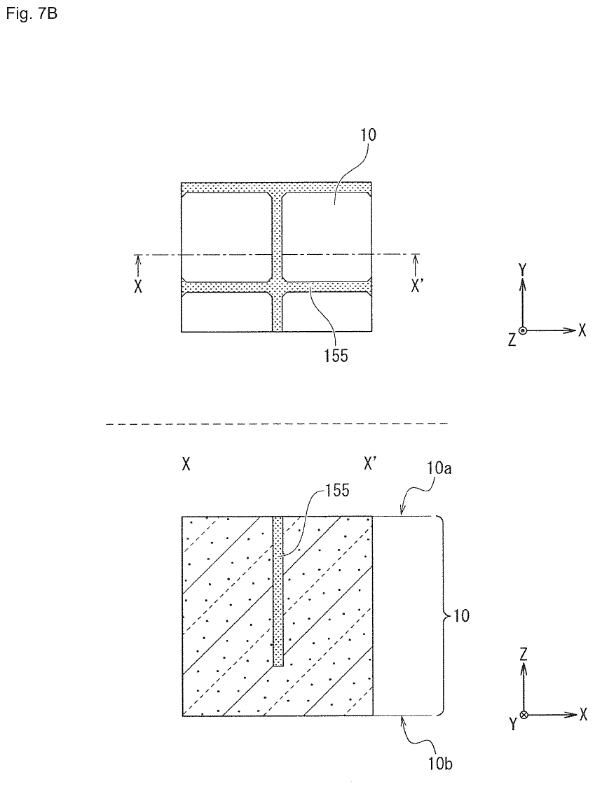

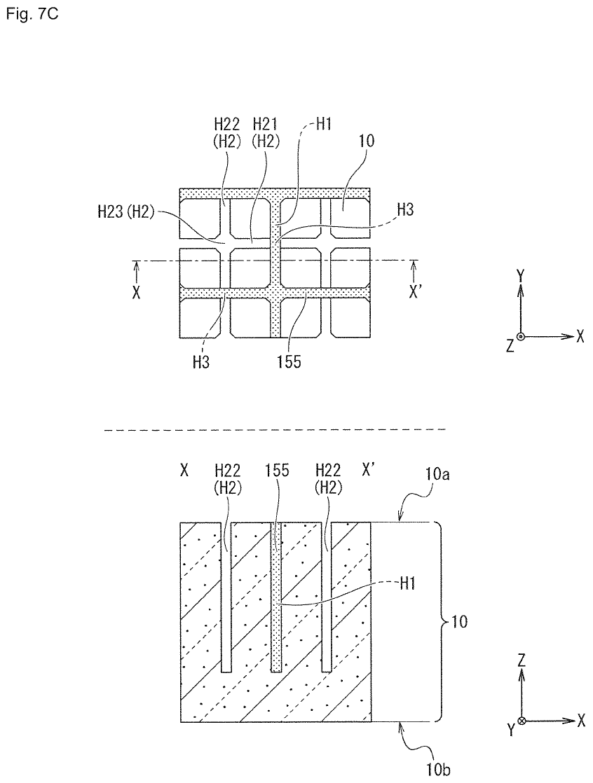

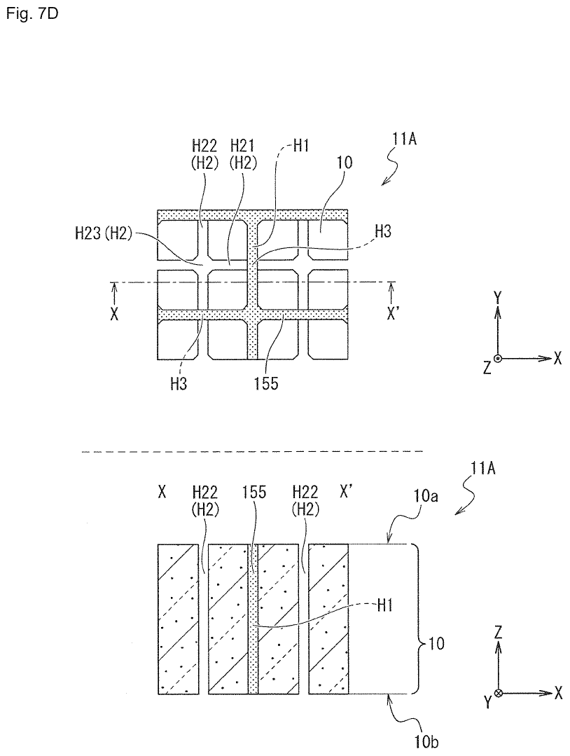

FIGS. 7A to 7D illustrate a method for manufacturing a pixel region 11A in the order of steps according to a second embodiment of the present disclosure. In the drawings of FIGS. 7A to 7D, the upper drawing is a plan view from a front side 10a of a semiconductor substrate 10, and the lower drawing is a cross-sectional view taken along line X-X′ of the upper plan view.

As shown in FIG. 7A, a manufacturing device etches the semiconductor substrate 10 from the front side 10a with a hard mask, which is not shown, to form a first trench H1. In the second embodiment, the first trench H1 is formed in a lattice pattern in a plan view from the direction of the normal (e.g., the Z-axis direction) to the front side 10a of the semiconductor substrate 10. The lattice pattern means a shape in which an L/S pattern parallel to the X-axis direction and a pattern parallel to the Y-axis direction are overlapped.

In this example, the first trench is formed in a lattice pattern such that the first trench is located at every other pixel in the X-axis direction and the Y-axis direction. In other words, the first trench H1 is formed so as to surround the two pixels in the X-axis direction and the two pixels in the Y-axis direction, that is, the four pixels in total.

The lattice-like first trench H1 includes a linear trench H11 (an example of “first linear trench” of the present disclosure) extended in the X-axis direction, a linear trench H12 (an example of “second linear trench” of the present disclosure) extended in the Y-axis direction, and an intersection region H13 (an example of “first intersection region” of the present disclosure) where the trench H11 and the trench H12 cross each other in plan view.

As shown in the upper plan view of FIG. 7A, the intersection region H13 is wider than the linear trenches H11 and H12 in plan view and is formed in a shape like a circle. The intersection region H13 is formed deeper than the linear trenches H11 and H12 from the front side 10a.

For example, the first trench H1 is formed by dry etching. In this case, ions fly from the X-axis direction to a planned region where the linear trench H11 is to be formed. Ions fly from the Y-axis direction to a planned region where the linear trench H12 is to be formed. In contrast, ions fly to the intersection region H13 from both the X-axis direction and the Y-axis direction. Since ions fly to the intersection region H13 from both the X-axis direction and the Y-axis direction, the intersection region H13 is easily etched. Thus, the intersection region H13 is wider than the trenches H11 and H12 and is formed in a shape like a circle. Moreover, the intersection region H13 is formed deeper than the trenches H11 and H12.

The first trench H1 may be formed by wet etching. The same applies to the case where the first trench H1 is formed by wet etching. An etchant enters, from the X-axis direction, a planned region where the linear trench H11 is to be formed. The etchant enters, from the Y-axis direction, a planned region where the linear trench H12 is to be formed. In contrast, the etchant enters the intersection region H13 from both the X-axis direction and the Y-axis direction. The intersection region H13 is easily etched because the etchant enters from both the X-axis direction and the Y-axis direction. Thus, the intersection region H13 is wider than the trenches H11 and H12 and is formed in a shape like a circle. Moreover, the intersection region H13 is formed deeper than the trenches H11 and H12.

After the first trench H1 is formed, the manufacturing device removes the hard mask, which is not shown, from above the front side 10a of the semiconductor substrate 10. The hard mask is removed by, for example, wet etching. The manufacturing device then performs wet cleaning such as cleaning on the semiconductor substrate 10 on which the first trench H1 is formed.

The removal of the hard mask by wet etching and wet processing such as cleaning may be performed consecutively in the same wet processing device. Furthermore, the hard mask may not be removed in the step of FIG. 7A and may be removed by performing CMP processing on the hard mask subsequently to a silicon oxide film 155 in the step of performing the CMP processing on the silicon oxide film 155, which will be described later.

Subsequently, as shown in FIG. 7B, the manufacturing device deposits the silicon oxide film 155 (an example of “first material film” of the present disclosure) on the front side 10a of the semiconductor substrate 10 by, for example, CVD to fill the first trench H1. The manufacturing device then performs CMP processing on the silicon oxide film 155, leaves the silicon oxide film 155 in the first trench H1, and removes the silicon oxide film 155 from a region other than the first trench H1.

Subsequently, as shown in FIG. 7C, the manufacturing device etches the semiconductor substrate 10 from the front side 10a with a hard mask, which is not shown, to form the second trench H2. In the second embodiment, the second trench H2 is formed in a lattice pattern in a plan view from the direction of normal (e.g., the Z-axis direction) to the front side 10a of the semiconductor substrate 10.

In this example, the lattice-like second trench H2 is formed to be displaced from the lattice-like first trench H1 by one pixel in the X-axis direction and the Y-axis direction. Thus, each of the pixels 12 is formed in a shape surrounded by the first trench H1 and the second trench H2. In plan view, one side of a pair of opposing sides of the pixel is adjacent to the first trench H1 (that is, adjacent to the silicon oxide film 155) and the other side is adjacent to the second trench H2.

The lattice-like second trench H2 includes a linear trench H21 (an example of “first linear trench” of the present disclosure) extended in the X-axis direction, a linear trench H22 (an example of “second linear trench” of the present disclosure) extended in the Y-axis direction, and an intersection region H23 (an example of “first intersection region” of the present disclosure) where the trench H21 and the trench H22 cross each other in plan view.

As shown in the upper plan view of FIG. 7C, the intersection region H23 is wider than the linear trenches H21 and H22 in plan view and is formed in a shape like a circle. The intersection region H23 is formed deeper than the linear trenches H21 and H22 from the front side 10a. The reason why the intersection region H23 is formed deeply is the same as the reason why the intersection region H13 is formed deeply.

Moreover, in the intersection region H3 where the second trench and the first trench H1 cross each other (an example of “second intersection region” of the present disclosure), for example, the silicon oxide film 155 is left unetched. Therefore, the intersection region H3 is not etched widely like the intersection region H23 of the second trench H2 and is not etched in a shape like a circle. The intersection region H3 is not etched deeply from the front side 10a like the intersection region H23 of the second trench H2.

After the second trench H2 is formed, the manufacturing device removes the hard mask, which is not shown, from above the front side 10a of the semiconductor substrate 10. The hard mask is removed by, for example, wet etching. The manufacturing device then performs wet processing such as cleaning on the semiconductor substrate 10 on which the second trench H2 is formed. The removal of the hard mask by wet etching and wet processing such as cleaning may be performed consecutively in the same wet processing device.

Subsequently, as shown in FIG. 7D, the manufacturing device performs CMP processing on the back side 10b of the semiconductor substrate 10 to expose the silicon oxide film 155 from the back side 10b. Through this process, the pixel region 11A is completed.

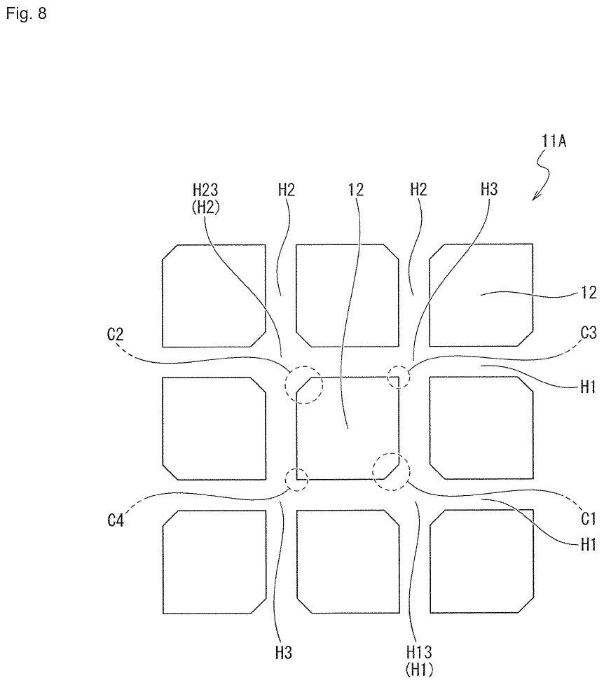

FIG. 8 illustrates the first and second trenches H1 and H2 and the shapes of the pixels 12 in the pixel region 11A according to the second embodiment of the present disclosure. In FIG. 8, the illustration of the silicon oxide film 155 embedded in the first trench H1 is omitted.

As shown in FIG. 8, in the pixel region 11A, each of the pixels 12 has a rectangular (or nearly rectangular) shape in plan view. Each of the pixels 12 has four corners C1, C2, C3, and C4 in a plan view from the Z-axis direction.

The corners C1 and C2 (an example of “first corner” of the present disclosure) are located on a first diagonal line of the pixel 12 and face each other. The corners C3 and C4 (an example of “second corner” of the present disclosure) are located on a second diagonal line, which crosses the first diagonal line of the pixel 12, and faces each other.

The corner C1 is a corner formed when the first trench H1 is formed, and is formed to face the intersection region H13. The corner C2 is a corner formed when the second trench H2 is formed, and is formed to face the intersection region H23.

Therefore, the corners C1 and C2 are each formed with a round shape and have a large radius of curvature.

In contrast, the corners C3 and C4 are corners that are formed by forming the second trench H2 crossing the first trench H1 in plan view, the first trench H1 being filled with the silicon oxide film 155. The corners C3 and C4 are formed to face the intersection region H3 where the silicon oxide film 155 is left.

As described above, the intersection region H3 is not etched widely like the intersection region H13 of the first trench H1 and the intersection region H23 of the second trench H2, and is not etched in a shape like a circle. Thus, the corners C3 and C4 are formed more angularly than the corners C1 and C2 and have a smaller radius of curvature than the corners C1 and C2.

The intersection region H13 is surrounded by the corners C1, which will be described later. The intersection region H23 is surrounded by the corners C23, which will be described later. The intersection region H3 is surrounded by the corners C3 or the corners C4, which will be described later.

In the X-axis direction, the intersection region H13 or the intersection region H23 and the intersection region H3 are arranged alternately. Also in the Y-axis direction, the intersection region H13 or the intersection region H23 and the intersection region H3 are arranged alternately.

### Effects of Second Embodiment

In the method for manufacturing the pixel region 11A according to the second embodiment of the present disclosure, in the step of forming the first trench H1, the first trench H1 is formed with a spacing at least twice (for example, twice as large as) the interval of the arranged pixels 12 in the X-axis direction and the Y-axis direction in plan view. In the step of forming the second trench H2, the second trench H2 is formed to cross the first trench in plan view. For example, in the step of forming the second trench H2, the second trench H2 is formed with a spacing at least twice (for example, twice as large as) the interval of the arranged pixels 12 in the X-axis direction and the Y-axis direction in plan view.

Also in this configuration, as in the first embodiment, the collapse of the pattern including the pixels 12 can be suppressed in wet processing after the first trench H1 is formed and wet processing after the second trench H2 is formed. In the step of forming the second trench H2 and the subsequent wet processing, the silicon oxide film 155 embedded in the first trench H1 serves as a support for the pattern including the pixels 12. This allows a finer pattern of the pixels 12.

Furthermore, the corners C3 and C4 of the intersection region H3, in which the first trench H1 and the second trench H2 cross each other, can be formed with a small radius of curvature (that is, angularly) in plan view. Thus, the light receiving area of the pixel 12 can be extended, thereby suppressing a decrease in the Qs (saturation charge amount) of the pixel 12. This can achieve both of a finer pattern of the pixels 12 and suppression of the decrease in Qs.

The pixel region 11A according to the second embodiment of the present disclosure includes the semiconductor substrate 10 having the front side 10a and the back side 10b, the plurality of pixels 12 arranged in a matrix on the semiconductor substrate 10, and inter-pixel separation portions 50, each being provided between the pixels on the semiconductor substrate 10 and separating one of the adjacent pixels 12 and the other pixel 12. Each of the pixels 12 has the corners C1 and C2 and the corners C3 and C4 having a smaller radius of curvature than the corners C1 and C2 in plan view.

With this configuration, the pixel region 11A can be formed using the manufacturing method according to the second embodiment, achieving a finer pattern of the pixels 12.

### Modification Example of Second Embodiment

### (1) First Modification Example

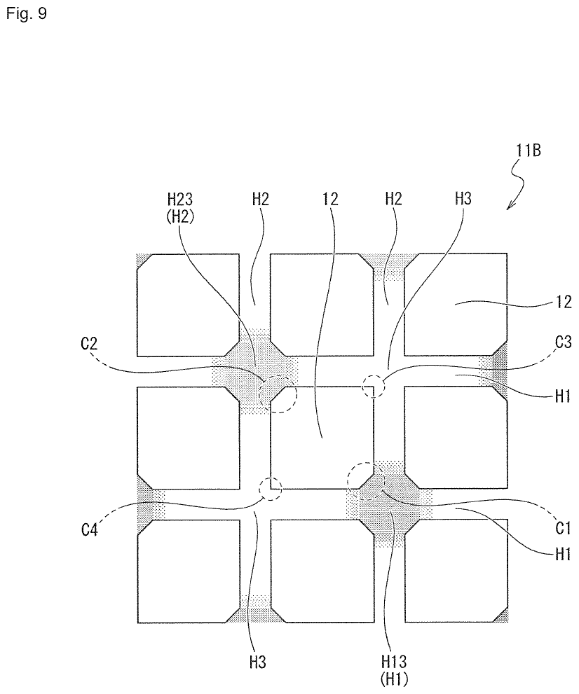

FIG. 9 is a plan view showing the configuration of a pixel region 11B according to a first modification example of the second embodiment of the present disclosure. The first modification example of the second embodiment is an example in which the second modification example of the first embodiment is applied to the second embodiment. In the first modification of the second embodiment, the step of grinding the back side 10b of the semiconductor substrate 10 described with reference to FIG. 7D is omitted. The inter-pixel separation portion 50 of the pixel region 11B is formed in a non-penetrating manner so as not to penetrate the front side and the back side of the semiconductor substrate 10. Specifically, the inter-pixel separation portion 50 is formed to a halfway position between the front side 10a and the back side 10b of the semiconductor substrate 10.

In the second embodiment, as described above, the intersection region H13 of the first trench H1 is formed deeper than the other regions of the first trench H1. The depth from the front side 10a to the bottom of the intersection region H13 of the first trench H1 is larger than the depth from the front side 10a to the bottom of the other region of the first trench H1. Likewise, the intersection region H23 of the second trench H2 is formed deeper than the other region of the second trench H2.

The depth from the front side 10a to the bottom of the intersection region H23 of the second trench H2 is larger than the depth from the front side 10a to the bottom of the other region of the second trench H2. In the pixel region 11B according to the first modification, the inter-pixel separation portion 50 is formed in a non-penetrating manner, so that the intersection regions H13 and H23 are left deeper than other regions.

Furthermore, the depths from the front sides 10a to the bottoms of the intersection regions H13 and H23 are larger than the depth from the front side 10a to the bottom of the intersection region H3, in which the first trench H1 and the second trench H2 cross each other.

In FIG. 9, in the first trench H1 and the second trench H2, the intersection regions H13 and H23 formed deeper than other regions are shown in a mesh pattern. In the X-axis direction and the Y-axis direction, the intersection regions H13 and H23 indicated in the mesh pattern are arranged every other pixel.

Also in this configuration, the collapse of the pattern including the pixels 12 can be suppressed in wet processing after the first trenches H1 are formed and wet processing after the second trenches H2 are formed. In the step of forming the second trench H2 and the subsequent wet processing, the silicon oxide film 155 embedded in the first trench H1 serves as a support for the pattern including the pixels 12. This allows a finer pattern of the pixels 12.

Furthermore, when a pixel transistor is placed on the back side 10b of the semiconductor substrate 10, the pixel transistor may be located without overlapping the intersection regions H13 and H23 in the Z-axis direction. With this configuration, the pixel transistor can be placed with a margin in the depth direction from the back side 10b unlike in the case where the pixel transistor is located while overlapping the intersection regions H13 and H23 in the Z-axis direction.

### Third Embodiment

The first and second embodiments described that the first trench H1 and the second trench H2 are formed at the same depth as the front side 10a of the semiconductor substrate 10. However, in the embodiments of the present disclosure, the first trench H1 and the second trench H2 may be formed at different depths.

Furthermore, one of the first and second trenches H1 and H2 may penetrate the semiconductor substrate 10, and the other may not penetrate the semiconductor substrate 10.

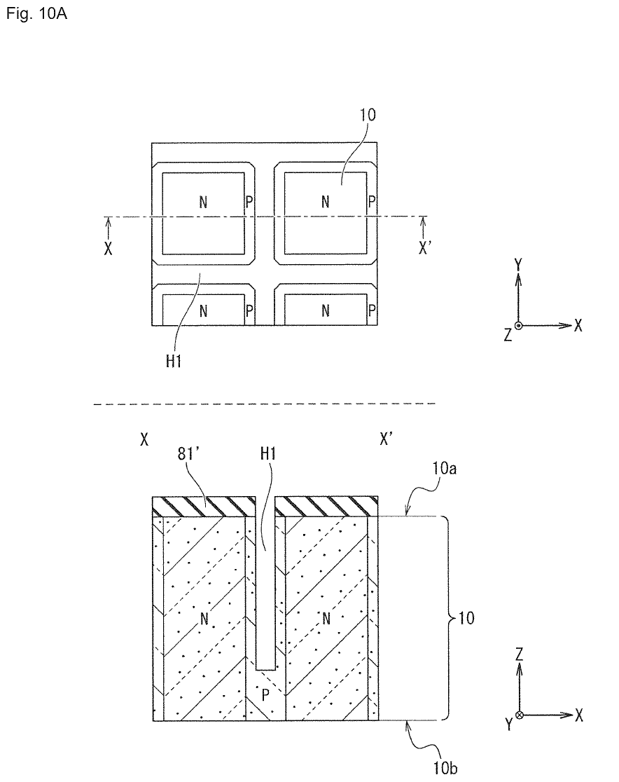

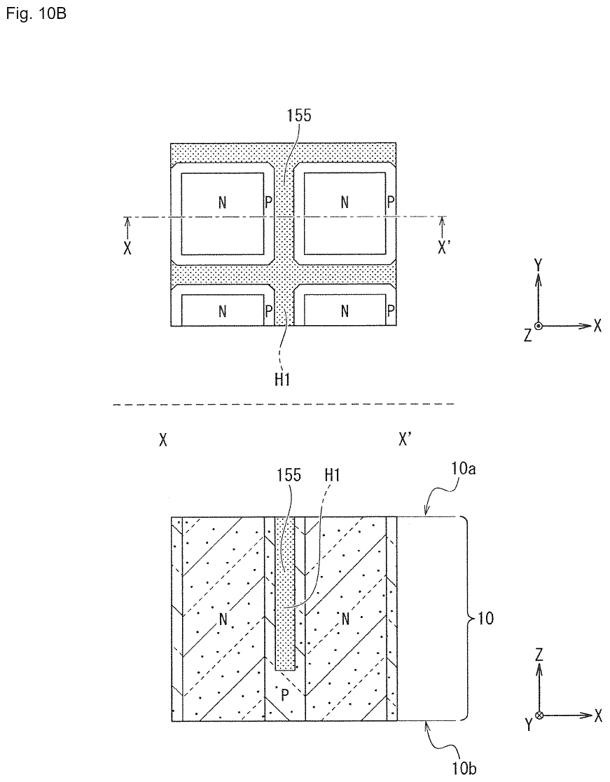

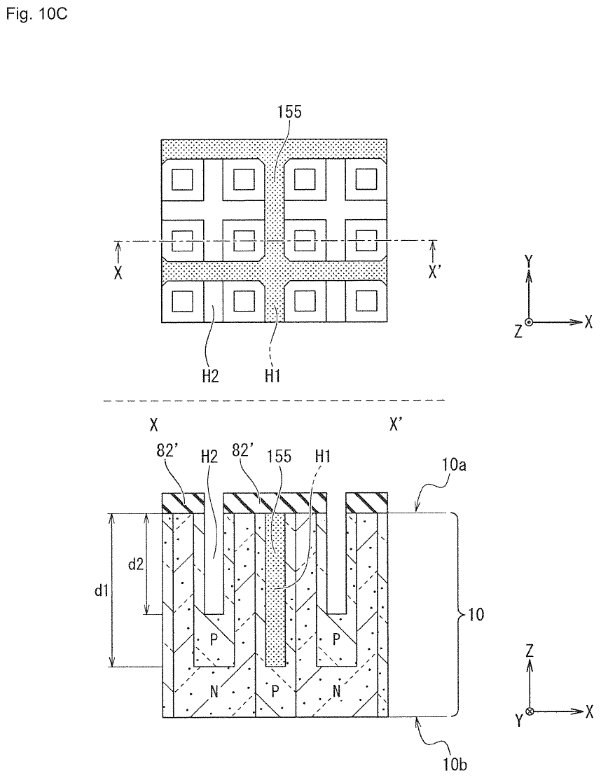

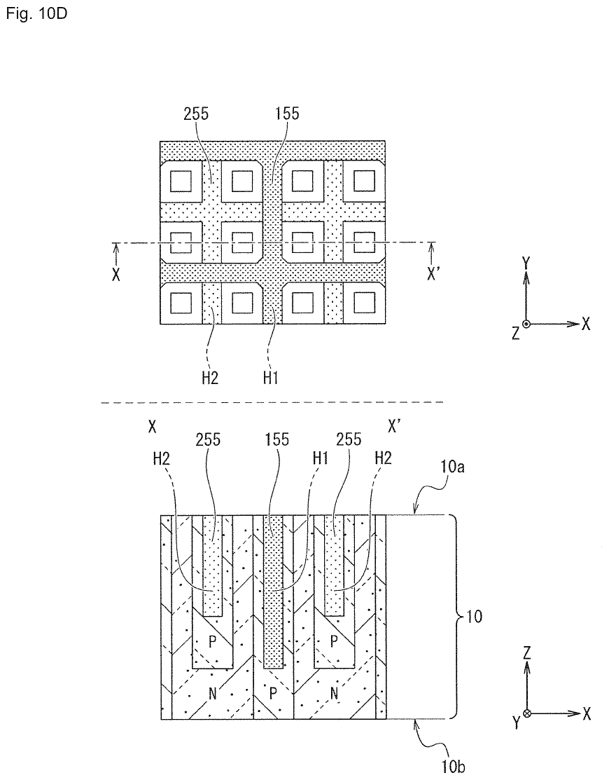

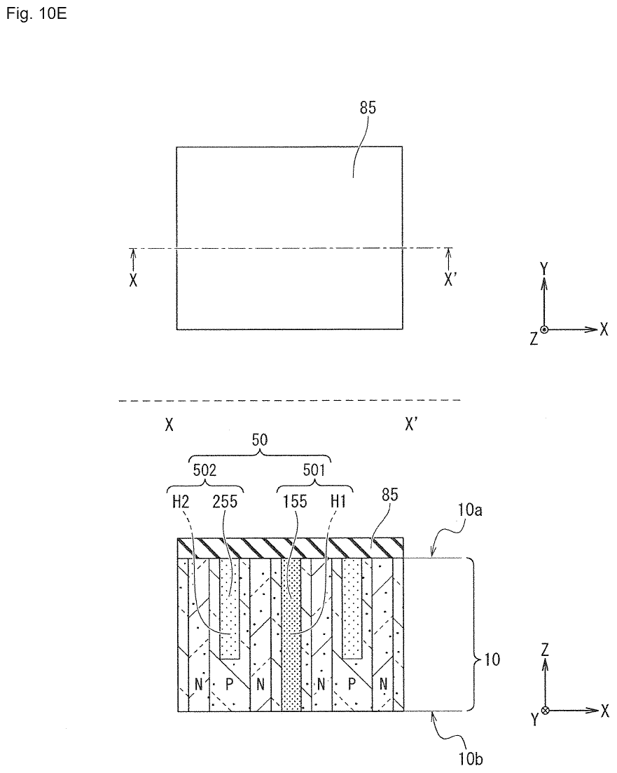

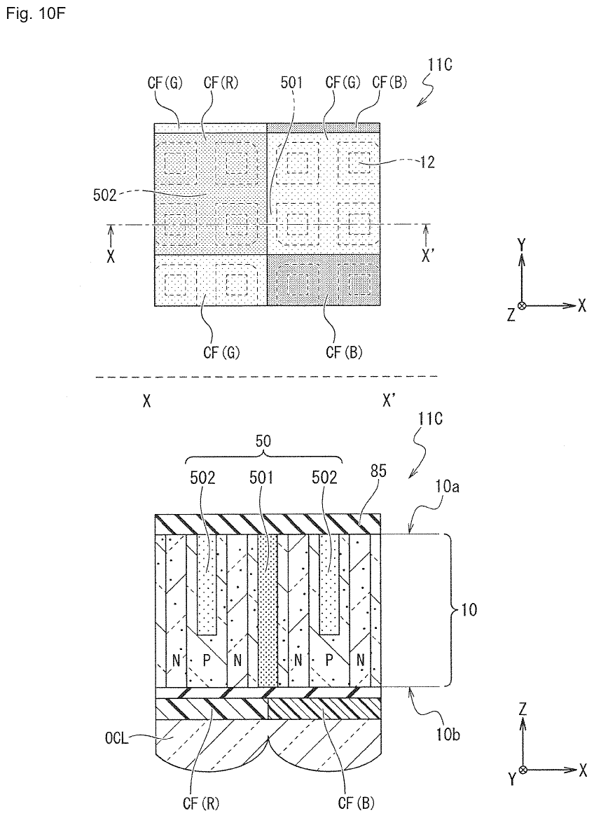

FIGS. 10A to 10F illustrate a method for manufacturing a pixel region 11C in the order of steps according to a third embodiment of the present disclosure. In the drawings of FIGS. 10A to 10F, the upper drawing is a plan view from a front side 10a of a semiconductor substrate 10, and the lower drawing is a cross-sectional view taken along line X-X′ of the upper plan view. In the upper plan views of FIGS. 10A and 10C, the illustration of insulating film patterns 81′ and 82′ (hard masks) is omitted in order to indicate a P-type region and an N-type region. In the upper plan view of FIG. 10F, color filters CF disposed on a back side 10b are shown to illustrate the positional relationship between the color filters CF and pixels 12.

As shown in FIG. 10A, the manufacturing device forms the insulating film pattern 81′ on the front side 10a of the N-type semiconductor substrate 10. The manufacturing device then forms a first trench H1 by etching the N-type semiconductor substrate 10 from the front side 10a with the insulating film pattern 81′ serving as a mask. In the third embodiment, as in the second embodiment, the first trench is formed in a lattice pattern such that the first trench is located at every other pixel in the X-axis direction and the Y-axis direction in plan view from the direction of the normal (e.g., the Z-axis direction) to the front side 10a of the semiconductor substrate 10. Thus, the first trench H1 is disposed in a region between the pixels 12 of different colors. After the first trench H1 is formed, the manufacturing device performs wet processing such as cleaning on the semiconductor substrate 10.

The manufacturing device then performs ion implantation of a P-type impurity (e.g., boron) into the N-type semiconductor substrate 10 with the insulating film pattern 81′ serving as a mask. After the ion implantation, the semiconductor substrate 10 is subjected to heat treatment to diffuse and activate the P-type impurity. This heat treatment may not be performed in the step of FIG. 10A and may be performed in combination with other heat treatments in the steps subsequent to FIG. 10A.

Subsequently, the manufacturing device deposits a silicon oxide film 155 (an example of “first material film” of the present disclosure) on the front side 10a of the semiconductor substrate 10 by, for example, CVD to fill the first trench H1. The manufacturing device then performs CMP processing on the silicon oxide film 155 and the insulating film pattern 81′, leaves the silicon oxide film 155 in the first trench H1 as shown in FIG. 10B, and removes the silicon oxide film 155 and the insulating film pattern 81′ from a region other than the first trench H1.

Subsequently, as shown in FIG. 10C, the manufacturing device forms the insulating film pattern 82′ on the front side 10a of the semiconductor substrate 10.

Thereafter, the manufacturing device etches the N-type semiconductor substrate 10 from the front side 10a with the insulating film pattern 82′ serving as a mask, so that second trench H2 is formed. In the third embodiment, as in the second embodiment, the second trench H2 is formed every other pixel in the X-axis direction and the Y-axis direction in plan view from the Z-axis direction, so that the second trench H2 is formed in a lattice pattern. The lattice-like second trench H2 is formed to be displaced from the lattice-like first trench H1 by one pixel in the X-axis direction and the Y-axis direction. Thus, the second trench H2 is disposed in a region between the pixels 12 of the same color.

In this example, the second trench H2 disposed between the pixels of the same color is formed at a shallower depth than the first trench H1 disposed between the pixels of different colors. For example, as shown in FIG. 10C, d1 represents the depth from the front side 10a of the first trench H1, and d2 represents the depth from the front side 10a of the second trench H2. In the step of forming the second trench H2, the second trench H2 is formed to satisfy d1>d2. After the second trench H2 is formed, the manufacturing device performs wet processing such as cleaning on the semiconductor substrate 10.

The manufacturing device then performs ion implantation of a P-type impurity (e.g., boron) into the semiconductor substrate 10 with the insulating film pattern 82′ serving as a mask. After the ion implantation, the semiconductor substrate 10 is subjected to heat treatment to diffuse and activate the P-type impurity. This heat treatment may not be performed in the step of FIG. 10C and may be performed in combination with other heat treatments in the step of FIG. 10D and the subsequent steps.

Subsequently, the manufacturing device deposits a silicon oxide film 255 (an example of “second material film” of the present disclosure) on the front side 10a of the semiconductor substrate 10 by, for example, CVD to fill the second trench H2.

The manufacturing device then performs CMP processing on the silicon oxide film 255 and the insulating film pattern 82′, leaves the silicon oxide film 255 in the second trench H2 as shown in FIG. 10D, and removes the silicon oxide film 255 and the insulating film pattern 82′ from a region other than the second trench H2.

Subsequently, the manufacturing device forms a pixel transistor (not shown) on the front side 10a of the semiconductor substrate 10. As shown in FIG. 10E, the manufacturing device then forms a wiring layer 85 on the front side 10a of the semiconductor substrate 10. The wiring layer 85 includes wirings and an interlayer insulating film covering the wirings. The wiring layer 85 may be a multilayer wiring layer in which a plurality of wirings and a plurality of interlayer insulating films are alternately stacked.

The manufacturing device then bonds another semiconductor substrate (not shown) to the front side 10a of the semiconductor substrate 10 with the wiring layer 85 interposed therebetween. The manufacturing device then grinds a back side 10b of the semiconductor substrate 10 such that the semiconductor substrate 10 has a foil thickness and the silicon oxide film 155 embedded in the first trench H1 is exposed from the back side 10b. In the step of grinding, the silicon oxide film 255 embedded in the second trench H2 is not exposed from the back side 10b.

Thus, the first trench H1 penetrates the semiconductor substrate 10 and the second trench H2 does not penetrate the semiconductor substrate 10. An inter-pixel separation portion 50 is formed with a penetrating separation portion 501 (see FIG. 10F) configured to include the first trench H1 penetrating the semiconductor substrate 10 and the silicon oxide film 155 embedded in the first trench H1, and non-penetrating separation portions 502 (see FIG. 10F), each being configured to include the second trench H2 not penetrating the semiconductor substrate 10 and the silicon oxide film 255 embedded in the second trench H2.

Thereafter, as shown in FIG. 10 F, the manufacturing device places the color filter CF on the back side 10b of the semiconductor substrate 10 with an insulating film 86 interposed therebetween, and places an on-chip lens OCL on the color filter CF.

In FIG. 10F, the color filter CF(R) is a red filter that transmits red light. The color filter CF(G) is a green filter that transmits green light. The color filter CF(B) is a blue filter that transmits blue light.

Through these steps, a pixel region 11C is formed. In the pixel region 11C, the first trench H1 and the second trench H2 are opened on the front side 10a. A depth d1 from the front side 10a to the bottom of the first trenches H1 and a depth d2 from the front side 10a to the bottom of the second trench H2 are different from each other. For example, d1>d2 is satisfied.

According to the third embodiment, as in the first and second embodiments, the collapse of the pattern including the pixels 12 can be suppressed in wet processing after the first trench H1 is formed and wet processing after the second trench H2 is formed. In the step of forming the second trench H2 and the subsequent wet processing, the silicon oxide film 155 embedded in the first trench H1 serves as a support for the pattern including the pixels 12. This allows a finer pattern of the pixels 12.

The penetrating separation portion configured to include the first trench H1 and the silicon oxide film 155 embedded in the first trench H1 is located while overlapping filters of different colors in the Z-axis direction, for example, between a red filter and a green filter and between a green filter and a blue filter, so that the pixels of different colors are separated from each other. This can suppress color mixture between the pixels of different colors. In contrast, the non penetrating separation portion configured to include the second trench H2 and the silicon oxide film 255 embedded in the second trench H2 is located while overlapping the filters of the same color in the Z-axis direction, for example, in a red filter, in a green filter, or in a blue filter. This can suppress reflection and scattering of light between the pixels of the same color.

### Fourth Embodiment

The second and third embodiments described that the silicon oxide film is embedded into the lattice-like first trench H1 and the lattice-like second trench H2. However, the embodiments of the present disclosure are not limited thereto. A polysilicon film may be embedded in the lattice-like first trench H1 and the lattice-like second trench H2.

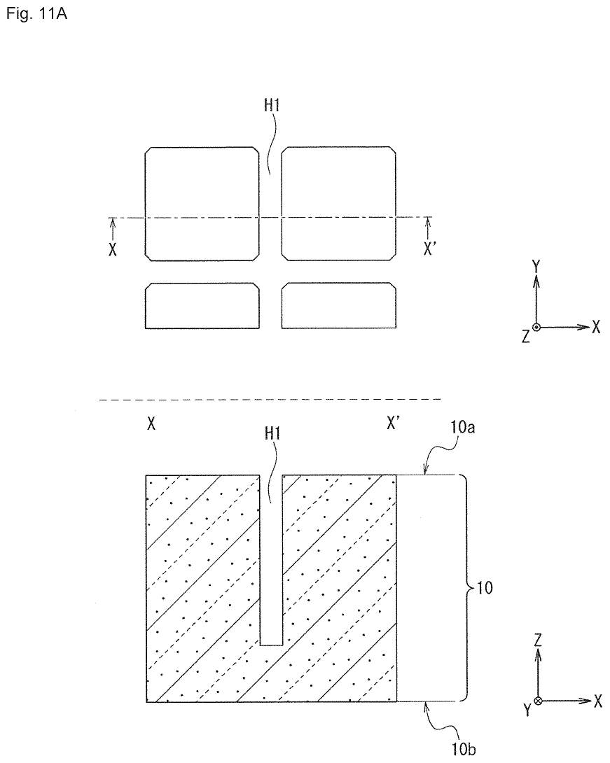

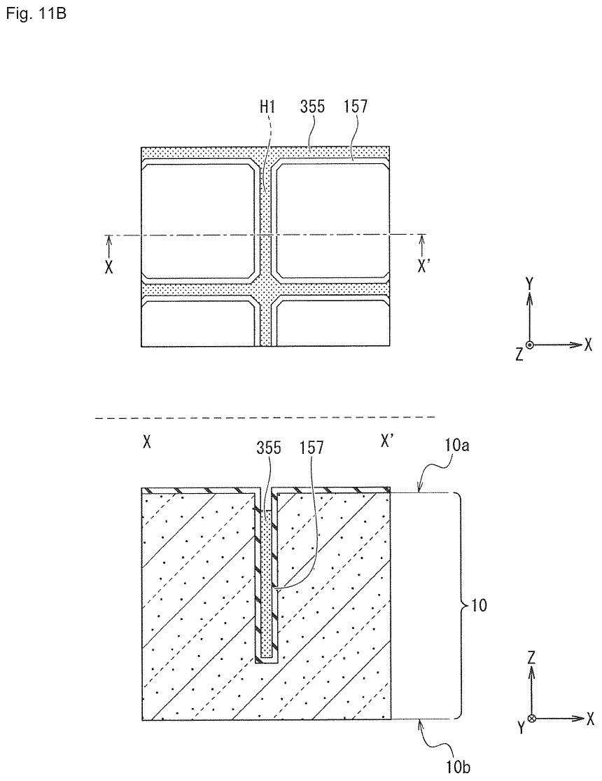

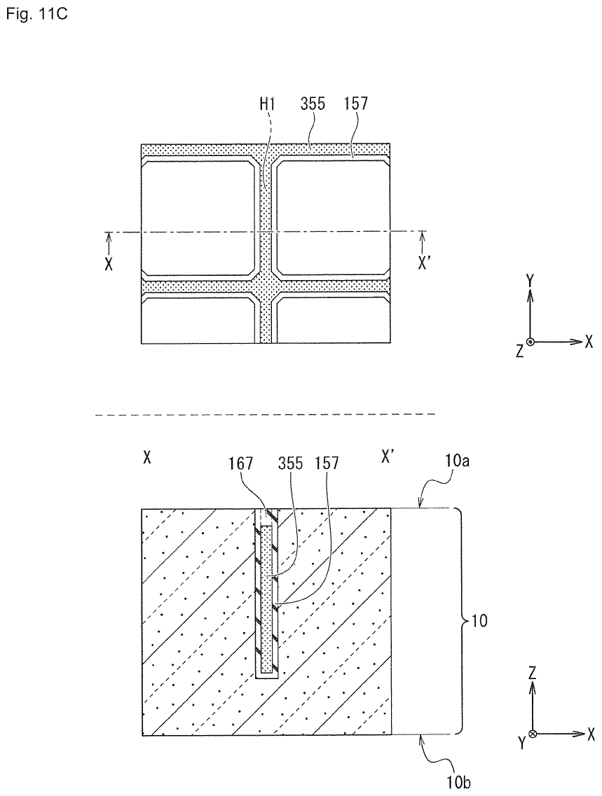

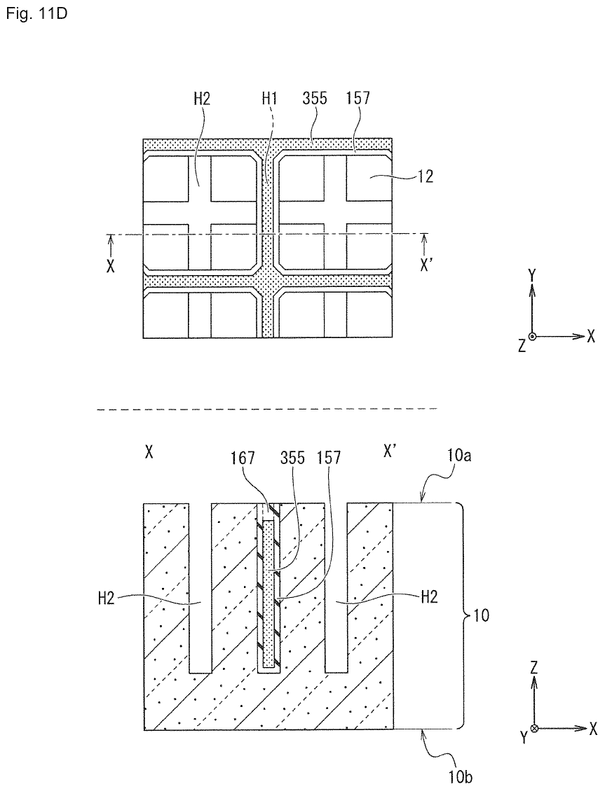

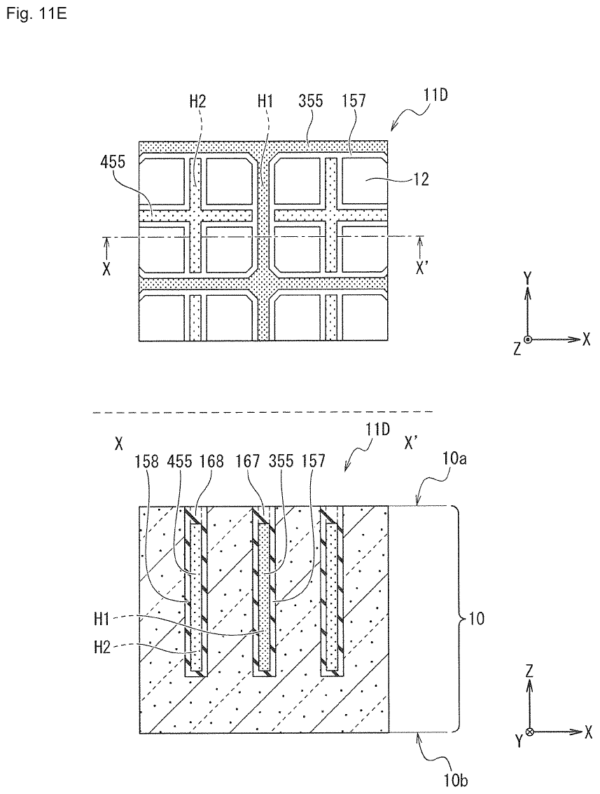

FIGS. 11A to 11E illustrate a method for manufacturing a pixel region 11D in the order of steps according to a fourth embodiment of the present disclosure. In the drawings of FIGS. 11A to 11D, the upper drawing is a plan view from a front side 10a of a semiconductor substrate 10, and the lower drawing is a cross-sectional view taken along line X-X′ of the upper plan view. In the upper plan views of FIGS. 11C and 11D, the illustration of a silicon oxide film 167 is omitted. In the top plan view of FIG. 11E, the illustration of the silicon oxide film 167 and a silicon oxide film 168 is omitted.

As shown in FIG. 11A, a manufacturing device etches the semiconductor substrate 10 from the front side 10a with a hard mask, which is not shown, to form a first trench H1. Also in the fourth embodiment, the first trench H1 is formed in a lattice pattern in plan view from the direction of the normal (e.g., the Z-axis direction) to the front side 10a of the semiconductor substrate 10 as in the second and third embodiments. In this example, the first trench is formed in a lattice pattern such that the first trench is located at every other pixel in the X-axis direction and the Y-axis direction.

After the first trench H1 is formed, the manufacturing device removes the hard mask, which is not shown, from above the front side 10a of the semiconductor substrate 10. The hard mask is removed by, for example, wet etching. The manufacturing device then performs wet processing such as cleaning on the semiconductor substrate 10 on which the first trench H1 is formed. The removal of the hard mask by wet etching and wet processing such as cleaning may be performed consecutively in the same wet processing device.

Subsequently, as shown in FIG. 11B, the manufacturing device forms a silicon oxide film 157 on the front side 10a of the semiconductor substrate 10 by, for example, CVD, and covers the front side 10a of the semiconductor substrate 10 and the sides and bottom of the first trench H1 with a silicon oxide film 157. The manufacturing device then deposits a polysilicon film 355 (an example of “first material film” of the present disclosure) on the front side 10a of the semiconductor substrate 10, on which the silicon oxide film 157 is formed, by, for example, CVD to fill the first trench H1. Thereafter, the manufacturing device etches back the polysilicon film 355, leaves the polysilicon film 355 in the first trench H1, and removes the polysilicon film 355 from a region other than the first trench H1.

The manufacturing device then forms the silicon oxide film 167 on the front side 10a of the semiconductor substrate 10 by, for example, CVD and covers the polysilicon film 355, which is left in the first trench H1, with the silicon oxide film 167. Thereafter, the manufacturing device performs CMP processing on the surface of the silicon oxide film 167, leaves the silicon oxide film 167 in the first trench H1 as shown in FIG. 11C, and removes the silicon oxide film 167 from a region other than the first trench H1. Thus, the entire periphery of the polysilicon film 355 left in the first trench H1 is covered with the silicon oxide films 157 and 167.

Thereafter, as shown in FIG. 11D, the manufacturing device etches the semiconductor substrate 10 from the front side 10a with a hard mask, which is not illustrated, so that the second trench H2 is formed. Also in the fourth embodiment, the second trench H2 is formed in a lattice pattern in plan view from the Z-axis direction as in the second and third embodiments.

In this example, a lattice-like second trench H2 is formed with positions shifted by one pixel in the X-axis direction and the Y-axis direction, respectively, relative to a lattice-like first trench H1. Thus, each of the plurality of pixels 12 is formed in a shape of being surrounded by the first trench H1 and the second trench H2. In a plan view, one side of a pair of opposing sides of the pixel is adjacent to the first trench H1 (that is, adjacent to the polysilicon film 355 via the silicon oxide film 157), and the other side is adjacent to the second trench H2.

The manufacturing device then performs wet processing such as cleaning on the semiconductor substrate 10 on which the second trench H2 is formed.

Subsequently, as shown in FIG. 11E, the manufacturing device sequentially forms a silicon oxide film 158, a polysilicon film 455, and a silicon oxide film 168 in the second trench H2. The methods for forming the films are the same as those for forming the silicon oxide film 157, the polysilicon film 355, and the silicon oxide film 167 in the first trench H1.

For example, the manufacturing device forms the silicon oxide film 158 on the front side 10a of the semiconductor substrate 10 by, for example, CVD, and covers the front side 10a of the semiconductor substrate 10 and the sides and bottom of the second trench H2 with the silicon oxide film 158. The manufacturing device then forms the polysilicon film 455 (an example of “second material film” of the present disclosure) on the front side 10a of the semiconductor substrate 10 by, for example, CVD. Thereafter, the manufacturing device etches back the polysilicon film 455, leaves the polysilicon film 455 in the second trench H2, and removes the polysilicon film 455 from a region other than the second trench H2.

The manufacturing device then forms the silicon oxide film 168 on the front side 10a of the semiconductor substrate 10 by, for example, CVD. The manufacturing device then performs CMP processing on the surface of the silicon oxide film 168, leaves the silicon oxide film 168 in the second trench H2, and removes the silicon oxide film 168 from a region other than the second trench H2. Thus, the entire periphery of the polysilicon film 455 left in the second trench H2 is covered with the silicon oxide films 158 and 168.

Through these steps, a pixel region 11D is formed. According to the fourth embodiment, as in the first to third embodiments, the collapse of the pattern including the pixels 12 can be suppressed in wet processing after the first trench H1 is formed and wet processing after the second trench H2 is formed. In the step of forming the second trench H2 and subsequent wet processing, the polysilicon film 355 embedded in the first trench H1 serves as a support for a pattern including the pixels 12. This allows a finer pattern of the pixels 12.

### Fifth Embodiment

The first to fourth embodiments described that the first trench H1 and the second trench H2 are formed from the front side 10a of the semiconductor substrate 10.

However, the embodiments of the present disclosure are not limited thereto. In the embodiments of the present disclosure, the first trench H1 and the second trench H2 may be formed from the back side 10b of the semiconductor substrate 10.

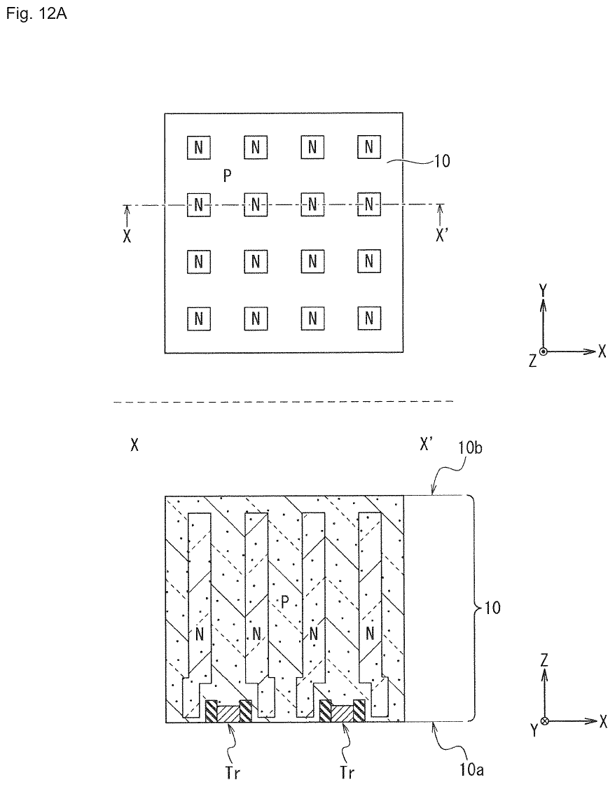

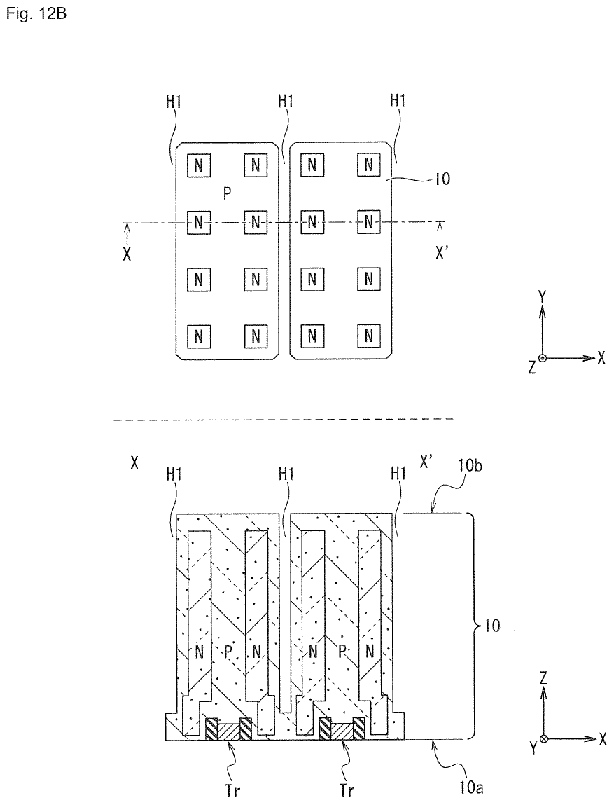

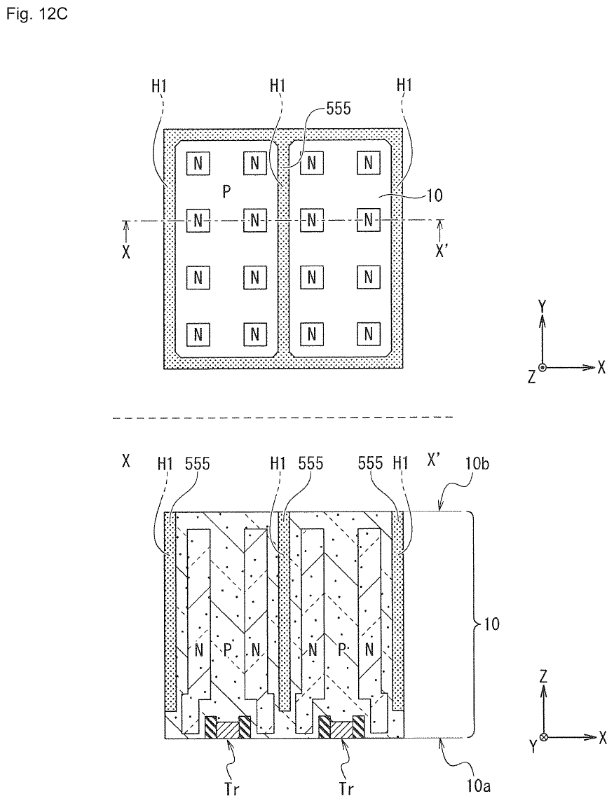

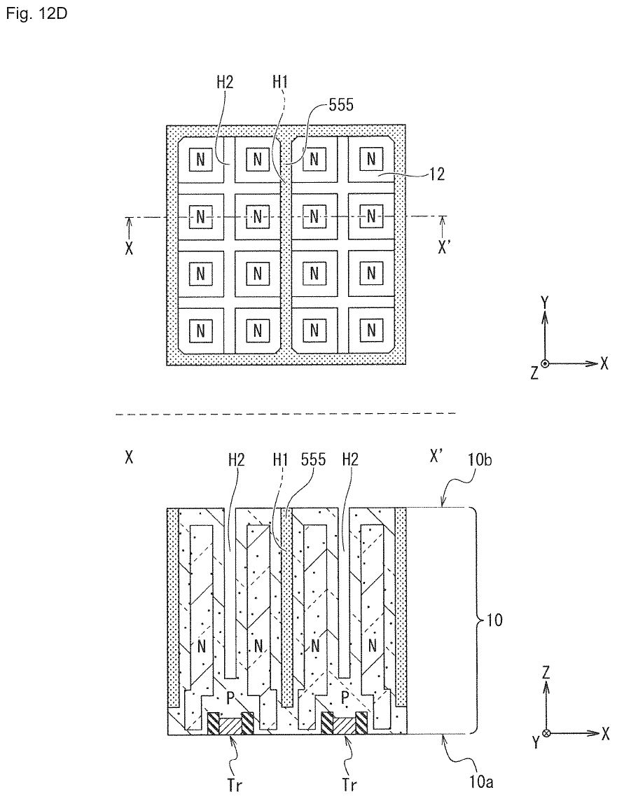

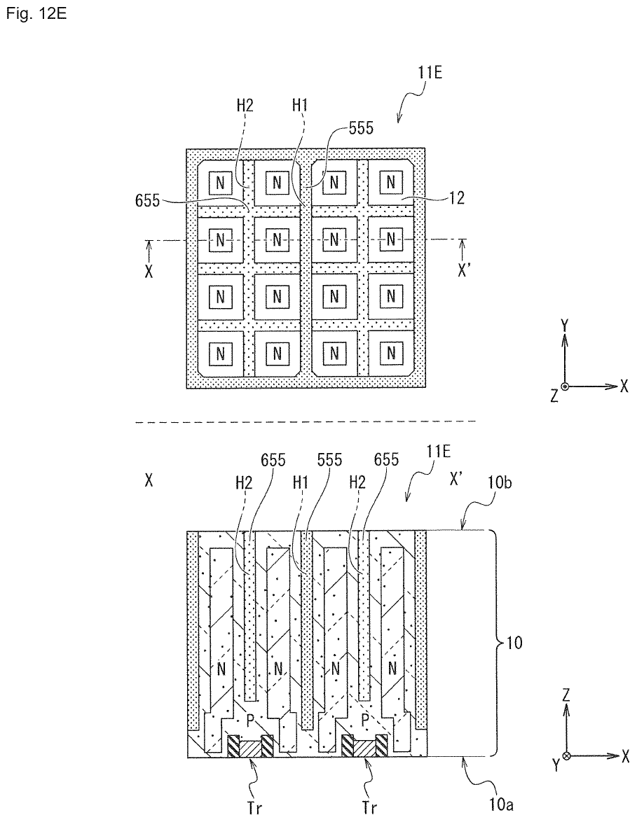

FIGS. 12A to 12E show the method for manufacturing a pixel region 11E in the order of steps according to a fifth embodiment of the present disclosure. In the drawings of FIGS. 12A to 12E, the upper drawing is a plan view from a back side 10b of a semiconductor substrate 10, and the lower drawing is a cross-sectional view of the upper plan view taken along line X-X′.

As shown in FIG. 12A, a manufacturing device forms a P-type region on an N-type semiconductor substrate 10 before forming a first trench H1. Furthermore, the manufacturing device forms a pixel transistor Tr on a front side 10a of the semiconductor substrate 10 (an example of “second surface” of the present disclosure).

Subsequently, as shown in FIG. 12B, the manufacturing device etches the semiconductor substrate 10 from the back side 10b (an example of “first surface” of the present disclosure) of the semiconductor substrate 10 with a hard mask, which is not shown, to form the first trench H1. The first trench H1 is formed in a lattice pattern in plan view from the direction of the normal (e.g., the Z-axis direction) to the back side 10b of the semiconductor substrate 10. In this example, the first trench H1 is formed in a lattice shape such that the first trench H1 is located at every other pixel in the X-axis direction and every four pixels in the Y-axis direction. In other words, the first trench H1 is formed so as to surround the two pixels in the X-axis direction and the four pixels in the Y-axis direction, that is, the eight pixels in total.

In this example, the first trench H1 is formed at a position not overlapping the pixel transistor Tr in the Z-axis direction. Accordingly, the first trench H1 may be formed to a deep position from the back side 10b of the semiconductor substrate 10.

After the first trench H1 is formed, the manufacturing device removes the hard mask, which is not shown, from above the front side 10a of the semiconductor substrate 10. The hard mask is removed by, for example, wet etching. The manufacturing device then performs wet processing such as cleaning on the semiconductor substrate 10 on which the first trench H1 is formed.

The removal of the hard mask by wet etching and wet processing such as cleaning may be performed consecutively in the same wet processing device. Furthermore, the hard mask may not be removed in the step of FIG. 12B and may be removed by performing CMP processing on the hard mask subsequently to a silicon oxide film 555 in the step of performing the CMP processing on the silicon oxide film 555, which will be described later.

Subsequently, as shown in FIG. 12C, the manufacturing device deposits the silicon oxide film 555 (an example of “first material film” of the present disclosure) on the back side 10b of the semiconductor substrate 10 by, for example, CVD to fill the first trench H1. The manufacturing device then performs CMP processing on the silicon oxide film 555, leaves the silicon oxide film 555 in the first trench H1, and removes the silicon oxide film 555 from a region other than the first trench H1.

Thereafter, as shown in FIG. 12D, the manufacturing device etches the semiconductor substrate 10 from the back side 10b with a hard mask, which is not shown, so that the second trench H2 is formed. In the fourth embodiment, the second trench H2 is formed in a lattice pattern between the pixels 12 in a frame surrounded by the first trench H1, in plan view from the Z-axis direction. In the step of forming the second trench H2, the second trench H2 is formed in a state in which one or two sides of the pixel 12 are adjacent to the silicon oxide film 555 embedded in the first trench H1.

In this example, the second trench H2 is formed at a position overlapping the pixel transistor Tr in the Z-axis direction. Accordingly, the depth of formation of the second trench H2 from the back side 10b is set to, for example, a depth smaller than that of the first trench H1, so that the second trench H2 does not reach the pixel transistor Tr.

After the second trench H2 is formed, the manufacturing device removes the hard mask, which is not shown, from above the front side 10a of the semiconductor substrate 10. The hard mask is removed by, for example, wet etching. The manufacturing device then performs wet processing such as cleaning on the semiconductor substrate 10 on which the second trench H2 is formed.

The removal of the hard mask by wet etching and wet processing such as cleaning may be performed consecutively in the same wet processing device. Furthermore, the hard mask may not be removed in the step of FIG. 12D and may be removed by performing CMP processing on the hard mask subsequently to a silicon oxide film 655 in the step of performing the CMP processing on the silicon oxide film 655, which will be described later.

Subsequently, as shown in FIG. 12E, the manufacturing device deposits the silicon oxide film 655 (an example of “second material film” of the present disclosure) on the back side 10b of the semiconductor substrate 10 by, for example, CVD to fill the second trench H2. The manufacturing device then performs CMP processing on the silicon oxide film 655, leaves the silicon oxide film 655 in the second trench H2, and removes the silicon oxide film 655 from a region other than the second trench H2.

Through these steps, a pixel region 11E is formed. According to the fifth embodiment, as in the first to fourth embodiments, the collapse of the pattern including the pixels 12 can be suppressed in wet processing after the first trench H1 is formed and wet processing after the second trench H2 is formed. In the formation step of the second trench H2 and subsequent wet processing, the silicon oxide film 555 embedded in the first trench H1 serves as a support for a pattern including the pixels 12. This allows a finer pattern of the pixels 12.

### Other Embodiments

While the present disclosure has been described with the embodiments, the modification examples, the availability example, and the application example as described above, the descriptions and figures that form parts of the present disclosure should not be understood as limiting the present disclosure. Various alternative embodiments, examples, and operational technologies will be apparent to those skilled in the art from the present disclosure. The application of the technique according to the present disclosure is not limited to an imaging device such as a CMOS image sensor and may be applied to, for example, a ranging device such as a direct ToF (Time of Flight) sensor or an indirect ToF sensor. That is, the light detection device of the present disclosure may be a ranging device as well as an imaging device. It is needless to say that the present technique includes various embodiments that are not described herein. At least one of various omissions, substitutions and modifications of constituent elements may be performed without departing from the gist of the embodiments and the modification examples described above. Furthermore, the advantageous effects described in the present specification are merely exemplary and not intended as limiting, and other advantageous effects may be produced.

The present disclosure can also be configured as follows:

(1) A method for manufacturing a light detection device, the method including the steps of:
forming a first trench by etching a portion of a semiconductor substrate between pixels from a first surface of the semiconductor substrate that has the first surface and a second surface located on the opposite side from the first surface and has the plurality of pixels arranged in a matrix; and
embedding a first material film into the first trench; and
forming a second trench by etching another portion between the pixels of the semiconductor substrate from the first surface of the semiconductor substrate having the embedded first material film.
   (2)

The method for manufacturing a light detection device according to (1), wherein in the step of forming the first trench,
the first trench is formed in parallel with a first direction in a plan view from the direction of the normal to the first surface, and
in the step of forming the second trench, the second trench is formed in parallel with a second direction that crosses the first direction in the plan view.
   (3)

The method for manufacturing a light detection device according to (1) or (2), further including the step of epitaxially growing, on the sides of the first trench, a first semiconductor layer made of the same material as the semiconductor substrate before the step of embedding the first material film into the first trench.

(4)

The method for manufacturing a light detection device according to any one of (1) to (3), further including the step of epitaxially growing, on the sides of the second trench, a second semiconductor layer made of the same material as the semiconductor substrate.

(5)

The method for manufacturing a light detection device according to (1), wherein in the step of forming the first trench,
the first trench is formed with a spacing at least twice the interval of the arranged pixels in a first direction and a second direction in a plan view from the direction of the normal to the first surface, the second direction crossing the first direction, and in the step of forming the second trench,
the second trench is formed to cross the first trench in the plan view.
   (6)

The method for manufacturing a light detection device according to (5), wherein in the step of forming the second trench, the second trench is formed with a spacing at least twice the interval of the arranged pixels in the first direction and the second direction in the plan view.

(7)

The method for manufacturing a light detection device according to (5) or (6), further including the step of embedding a second material film into the second trench.

(8)

The method for manufacturing a light detection device according to any one of (1) to (7), wherein a polycrystalline film or an amorphous film is used as the first material film.

(9)

A light detection device including: a semiconductor substrate having a first surface and a second surface located on the opposite side from the first surface;
a plurality of pixels arranged in a matrix on the semiconductor substrate; and an inter-pixel separation portion that is provided between the pixels of the semiconductor substrate and separates one of the adjacent pixels and the other pixel,
wherein the inter-pixel separation portion includes:
a first trench parallel to a first direction in a plan view from the direction of the normal to the first surface;
a second trench parallel to a second direction that crosses the first direction in the plan view;
an intersection region where the first trench and the second trench cross each other; and
a first material film embedded in the first trench,
the first material film protruding from the first trench to the intersection region.
   (10)

The light detection device according to (9), wherein a distance between one of the pixels adjacent to each other in the first direction and the other pixel is shorter than a distance between one of the first material films adjacent to each other in the first direction and the other first material film.

(11)

The light detection device according to (9) or (10), wherein each of the pixels includes
a single-crystal semiconductor layer formed on an outer periphery of the pixel by an epitaxial growth method.
   (12)

The light detection device according to (11), wherein the semiconductor layer includes
a first semiconductor layer extending along the first direction; and
a second semiconductor layer extending along the second direction.
   (13)

The light detection device according to any one of (9) to (12), wherein the second trench has a gap.

(14)

The light detection device according to any one of (9) to (13), wherein the first material film is a polycrystalline film or an amorphous film.

(15)

A light detection device including: a semiconductor substrate having a first surface and a second surface located on the opposite side from the first surface;
a plurality of pixels arranged in a matrix on the semiconductor substrate; and an inter-pixel separation portion that is provided between the pixels of the semiconductor substrate and separates one of the adjacent pixels and the other pixel,
wherein in a plan view from the direction of the normal to the first surface, each of the pixels has first corners; and
second corners, each having a smaller radius of curvature than the first corner.
   (16)

The light detection device according to (15), wherein, in each of the pixels, the pair of first corners is disposed on a first diagonal line, and the pair of second corners is disposed on a second diagonal line that crosses the first diagonal line.

(17)

The light detection device according to (15) or (16), wherein the inter-pixel separation portion includes:
a first linear trench parallel to a first direction in a plan view from the direction of the normal to the first surface;
a second linear trench parallel to a second direction that crosses the first direction in the plan view; and
an intersection region where the first linear trench and the second linear trench cross each other,
the intersection region having, in the plan view,
a first intersection region surrounded by the first corners; and
a second intersection region surrounded by the second corners.
   (18)

The light detection device according to (17), wherein in the first direction and a second direction serving as the first direction,
the first intersection region and the second intersection region are arranged alternately.
   (19) The light detection device according to (17) or (18), wherein the inter-pixel separation portion is formed from the first surface to a halfway position between the first surface and the second surface, and
a depth from the first surface to the bottom of the first intersection region is larger than a depth from the first surface to the bottom of the second intersection region.
   (20)

The light detection device according to (17) or (18), wherein the first trench and the second trench are opened on the first surface, and
a depth from the first surface to the bottom of the first trench and a depth from the first surface to the bottom of the second trench are different from each other.

### REFERENCE SIGNS LIST

1 Imaging device
10 Semiconductor substrate
10a Front side
10b Back side
11, 11A, 11B, 11C, 11D, 11E Pixel region
12 Pixel
13 Vertical drive circuit
14 Column signal processing circuit
15 Horizontal drive circuit
16 Output circuit
17 Control circuit
22 Horizontal signal line
23 Vertical signal line
24 Data output signal line
30 Readout circuit
31 Photodiode
32 Transfer transistor
33 Floating diffusion
34 Amplification transistor
35 Selection transistor
36 Reset transistor
50 Inter-pixel separation portion
55, 355, 455 Polysilicon film
57, 58, 81, 82 Insulating film
81′, 82′ Insulating film pattern (hard mask)
85 Wiring layer
86 Insulating film
120 Central portion
121 First semiconductor layer
122 Second semiconductor layer
155, 157, 158, 167, 168, 255, 555, 655 Silicon oxide film
501 Penetrating separation portion
502 Non-penetrating separation portion
551 Protruding portion
C1, C2, C3, C4 Corner
CF, CF(R), CF(G), CF(B) Color filter
H1 First trench
H2 Second trench
H3, H13, H23 Intersection region
H11, H12, H21, H22 (Linear) trench
OCL On-chip lens
PR1, PR2 Photoresist
PR1′, PR2′ Resist pattern
Tr Pixel transistor

1. A method for manufacturing a light detection device, the method comprising the steps of: forming a first trench by etching a portion of a semiconductor substrate between pixels from a first surface of the semiconductor substrate that has the first surface and a second surface located on an opposite side from the first surface and has the plurality of pixels arranged in a matrix;
embedding a first material film into the first trench; and
forming a second trench by etching another portion between the pixels of the semiconductor substrate from the first surface of the semiconductor substrate having the embedded first material film.

2. The method for manufacturing a light detection device according to claim 1, wherein in the step of forming the first trench,
the first trench is formed in parallel with a first direction in a plan view from a direction of normal to the first surface, and
in the step of forming the second trench,
the second trench is formed in parallel with a second direction that crosses the first direction in the plan view.

3. The method for manufacturing a light detection device according to claim 1, further comprising the step of epitaxially growing, on sides of the first trench, a first semiconductor layer made of the same material as the semiconductor substrate before the step of embedding the first material film into the first trench.

4. The method for manufacturing a light detection device according to claim 1, further comprising the step of epitaxially growing, on sides of the second trench, a second semiconductor layer made of the same material as the semiconductor substrate.

5. The method for manufacturing a light detection device according to claim 1, wherein in the step of forming the first trench,
the first trench is formed with a spacing at least twice an interval of the arranged pixels in a first direction and a second direction in a plan view from a direction of normal to the first surface, the second direction crossing the first direction, and
in the step of forming the second trench, the second trench is formed to cross the first trench in the plan view.

6. The method for manufacturing a light detection device according to claim 5, wherein in the step of forming the second trench,
the second trench is formed with a spacing at least twice the interval of the arranged pixels in the first direction and the second direction in the plan view.

7. The method for manufacturing a light detection device according to claim 5, further comprising the step of embedding a second material film into the second trench.

8. The method for manufacturing a light detection device according to claim 1, wherein a polycrystalline film or an amorphous film is used as the first material film.

9. A light detection device comprising: a semiconductor substrate having a first surface and a second surface located on an opposite side from the first surface;
a plurality of pixels arranged in a matrix on the semiconductor substrate; and
an inter-pixel separation portion that is provided between the pixels of the semiconductor substrate and separates one of the adjacent pixels and the other pixel,
wherein the inter-pixel separation portion includes:
a first trench parallel to a first direction in a plan view from a direction of normal to the first surface;
a second trench parallel to a second direction that crosses the first direction in the plan view;
an intersection region where the first trench and the second trench cross each other; and
a first material film embedded in the first trench,
the first material film protruding from the first trench to the intersection region.

10. The light detection device according to claim 9, wherein a distance between one of the pixels adjacent to each other in the first direction and the other pixel is shorter than a distance between one of the first material films adjacent to each other in the first direction and the other first material film.

11. The light detection device according to claim 9, wherein each of the pixels includes a single-crystal semiconductor layer formed on an outer periphery of the pixel by an epitaxial growth method.

12. The light detection device according to claim 11, wherein the semiconductor layer includes
a first semiconductor layer extending along the first direction; and
a second semiconductor layer extending in the second direction.

13. The light detection device according to claim 9, wherein a gap is formed on the second trench.

14. The light detection device according to claim 9, wherein the first material film is a polycrystalline film or an amorphous film.

15. A light detection device comprising: a semiconductor substrate having a first surface and a second surface located on an opposite side from the first surface;
a plurality of pixels arranged in a matrix on the semiconductor substrate; and
an inter-pixel separation portion that is provided between the pixels of the semiconductor substrate and separates one of the adjacent pixels and the other pixel,
wherein in a plan view from a direction of normal to the first surface, each of the pixels has
first corners; and
second corners, each having a smaller radius of curvature than the first corner.

16. The light detection device according to claim 15, wherein, in each of the pixels, the pair of first corners is disposed on a first diagonal line, and
the pair of second corners is disposed on a second diagonal line that crosses the first diagonal line.

17. The light detection device according to claim 15, wherein the inter-pixel separation portion includes:
a first linear trench parallel to a first direction in a plan view from the direction of the normal to the first surface;
a second linear trench parallel to a second direction that crosses the first direction in the plan view; and
an intersection region where the first linear trench and the second linear trench cross each other,
the intersection region having, in the plan view,
a first intersection region surrounded by the first corners; and
a second intersection region surrounded by the second corners.

18. The light detection device according to claim 17, wherein in the first direction and a second direction serving as the first direction,
the first intersection region and the second intersection region are arranged alternately.

19. The light detection device according to claim 17, wherein the inter-pixel separation portion is formed from the first surface to a halfway position between the first surface and the second surface, and
a depth from the first surface to a bottom of the first intersection region is larger than a depth from the first surface to a bottom of the second intersection region.

20. The light detection device according to claim 17, wherein the first trench and the second trench are opened on the first surface, and
a depth from the first surface to a bottom of the first trench and a depth from the first surface to a bottom of the second trench are different from each other.
